(19) United States
(12) Patent Application Publication
(10) Pub. No.: US 2026/0068757 A1
(43) Pub. Date: Mar. 5, 2026

(54) STACKED SEMICONDUCTOR DEVICES

(71) Applicant: SK hynix Inc., Icheon-si Gyeonggi-do (KR)

(72) Inventors: Ju Hyung PARK, Icheon-si Gyeonggi-do (KR); Ha Jun JEONG, Icheon-si Gyeonggi-do (KR)

(73) Assignee: SK hynix Inc., Icheon-si Gyeonggi-do (KR)

(21) Appl. No.: 19/032,323

(22) Filed: Jan. 20, 2025

(30) Foreign Application Priority Data
Sep. 2, 2024 (KR) 10-2024-0118863

(51) Int. Cl. H01L 25/065; G11C 11/406

(52) U.S. Cl. CPC H01L 25/0657; G11C 11/40611; G11C 11/40615; G11C 11/40618

(57) ABSTRACT

A stack memory device includes a base chip, a first slice chip stacked over the base chip, and a second slice chip stacked over the first slice chip. The base chip includes a slice control circuit configured to control the first slice chip and the second slice chip such that a refresh operation is performed according to a refresh mode of the first slice chip and a refresh mode of the second slice chip when a refresh bank signal is generated that refreshes banks included in the first slice chip and the second slice chip.

### CROSS-REFERENCE TO RELATED APPLICATIONS

The present application claims priority under 35 U.S.C. § 119(a) to Korean Patent Application No. 10-2024-0118863, filed in the Korean Intellectual Property Office on Sep. 2, 2024, the entire contents of which application is incorporated herein by reference.

### BACKGROUND

### 1. Technical Field

The present disclosure relates to semiconductor memory devices, including but not limited to stacked memory devices.

### 2. Related Art

Stacked memory systems such as high bandwidth memory (HBM) devices are used in a wide range of applications due to their considerable bandwidth. Stacked memory systems include a stacked memory device including a base chip and a plurality of slice chips interconnected by through-silicon vias (TSVs). The stacked memory device includes a physical interface, such as a physical layer for communication with a processor, and the physical layer is constructed for high-speed data transmission and efficient communication.

Each of the plurality of the slice chips of the stacked memory device includes a plurality of memory cells in which data is stored. Because the data stored in the memory cells included in the slice chips dissipates over time, a refresh operation is utilized to re-write the data in the memory cells at regular intervals.

### SUMMARY

In an embodiment, a stacked memory device may include a base chip, a first slice chip stacked over the base chip, and a second slice chip stacked over the first slice chip. The base chip may include a slice control circuit configured to control the first slice chip and the second slice chip such that a refresh operation is performed according to a refresh mode of the first slice chip and a refresh mode of the second slice chip when a refresh bank signal is generated that refreshes banks included in the first slice chip and the second slice chip.

In an embodiment, a stacked memory device may include a base chip, a first slice chip stacked over the base chip, and a second slice chip stacked over the first slice chip. The base chip may include a control circuit configured to generate a clock signal that toggles when a refresh bank signal is generated that refreshes banks included in the first slice chip and the second slice chip, and a first slice refresh control circuit configured to select a refresh mode of the first slice chip, based on the clock signal, a reset signal, and a slice identification (ID).

In an embodiment, a method may include controlling, by a slice control circuit for a first slice chip and a second slice chip of a stacked memory device, the first slice chip such that a refresh operation is performed according to a refresh mode of the first slice chip when a refresh bank signal is generated that refreshes banks included in the first slice chip and the second slice chip; and controlling, by the slice control circuit, the second slice chip such that a refresh operation is performed according to a refresh mode of the second slice chip when a refresh bank signal is generated that refreshes banks included in the first slice chip and the second slice chip.

### BRIEF DESCRIPTION OF THE DRAWINGS

FIG. 1 is a block diagram illustrating a stacked memory device according to an embodiment of the present disclosure.

FIG. 2 is a block diagram illustrating a slice control circuit according to an embodiment of the present disclosure.

FIG. 3 is a circuit diagram illustrating a first mode control signal generation circuit according to an embodiment of the present disclosure.

FIG. 4 is a table including data during operation of a first mode control signal generation circuit according to an embodiment of the present disclosure.

FIG. 5 is a circuit diagram illustrating a second mode control signal generation circuit according to an embodiment of the present disclosure.

FIG. 6 is a table including data during an operation of a second mode control signal generation circuit according to an embodiment of the present disclosure.

FIG. 7 is a circuit diagram illustrating a third mode control signal generation circuit according to an embodiment of the present disclosure.

FIG. 8 is a table including data during operation of a third mode control signal generation circuit according to an embodiment of the present disclosure.

FIG. 9 is a circuit diagram illustrating a fourth mode control signal generation circuit according to an embodiment of the present disclosure.

FIG. 10 is a table including data during operation of a fourth mode control signal generation circuit according to an embodiment of the present disclosure.

FIG. 11 is a circuit diagram illustrating a first refresh mode selecting signal generation circuit according to an embodiment of the present disclosure.

FIG. 12 is a table including data during operation of a first refresh mode selecting signal generation circuit according to an embodiment of the present disclosure.

FIG. 13 is a circuit diagram illustrating a second refresh mode selecting signal generation circuit according to an embodiment of the present disclosure.

FIG. 14 is a table including data during operation of a second refresh mode selecting signal generation circuit according to an embodiment of the present disclosure.

FIG. 15 is a circuit diagram illustrating a refresh mode selecting signal generation circuit according to an embodiment of the present disclosure.

FIG. 16 is a table including data during operation of a third refresh mode selecting signal generation circuit according to an embodiment of the present disclosure.

FIG. 17 is a circuit diagram illustrating a fourth refresh mode selecting signal generation circuit according to an embodiment of the present disclosure.

FIG. 18 is a table including data during operation of a fourth refresh mode selecting signal generation circuit according to an embodiment of the present disclosure.

FIG. 19 is a circuit diagram illustrating a first refresh control circuit according to an embodiment of the present disclosure.

FIG. 20 is a timing diagram during a refresh mode performed for multiple slice chips according to an embodiment of the present disclosure.

FIG. 21 and FIG. 22 are block diagrams illustrating examples of stacked memory systems according to the present disclosure.

### DETAILED DESCRIPTION

Terms such as “first” and “second” are used to distinguish between various elements and do not imply size, order, priority, quantity, or importance of the elements. For example, a first element may be referred to as a second element in one example, and the second element may be referred to as a first element in another example.

When an element is referred to as “connected” to another element, the elements may be connected directly or through one or more intervening elements between the elements. When two elements are referred to as “directly connected” one element is directly connected to the other element without an intervening element between the two elements.

When one element is identified as “on” or “over” another element, the elements may directly contact each other or an intervening element may be disposed between the elements.

Terms such as “over,” “on,” “high,” “low,” “column,” “row,” “level,” and other terms implying relative spatial relationship or orientation are utilized only for the purpose of ease of description or reference to a drawing and are not otherwise limiting.

The term “bit set” includes a combination of logic levels of bits included in a signal. When the logic level of the bits included in the signal is changed, the bit set of the signal is different. For example, when the signal includes a first combination of two bits, the logic bit set of the signal is a first bit set, and when the signal includes a second combination of two bits, the bit set of the signal is a second bit set.

Embodiments of the present disclosure are described in detail with reference to the accompanying drawings. Specific structural or functional descriptions of embodiments are provided as examples for illustrative purposes to describe concepts that are disclosed in the present application. Examples or embodiments in accordance with the concepts may be carried out in various forms, and the scope of the present disclosure is not limited to the examples or embodiments described in this specification.

The refresh operation is performed in various ways in which the quantity of memory cells included in the slice chips and refreshed together is changed. When all the slice chips included in the stacked memory device are refreshed in the same way, current consumption increases rapidly as the quantity of slice chips that are refreshed together increases.

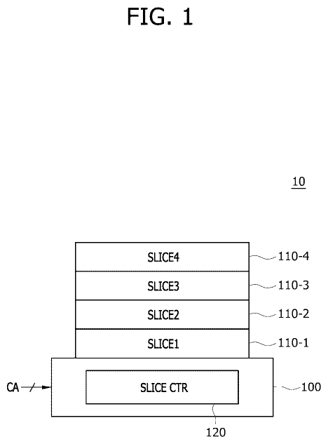

FIG. 1 is a block diagram illustrating a stacked memory device 10 according to an embodiment of the present disclosure.

As shown in FIG. 1, the stacked memory device 10 includes a base chip 100, a first slice chip 110-1, a second slice chip 110-2, a third slice chip 110-3, and a fourth slice chip 110-4. The first slice chip 110-1 is stacked over or on the base chip 100, the second slice chip 110-2 is stacked over or on the first slice chip 110-1, the third slice chip 110-3 is stacked over or on the second slice chip 110-2, and the fourth slice chip 110-4 is stacked over or on the third slice chip 110-3. The quantity L of slice chips stacked over the base chip 100 may be, for example, one of 8, 12, 16, and so forth, where L is a positive integer. Through-silicon vias TSVs are disposed in each of the base chip 100, the first slice chip 110-1, the second slice chip 110-2, the third slice chip 110-3, and the fourth slice chip 110-4. The through-silicon vias penetrate the base chip 100, the first slice chip 110-1, the second slice chip 110-2, the third slice chip 110-3, and the fourth slice chip 110-4, and the base chip 100, the first slice chip 110-1, the second slice chip 110-2, the third slice chip 110-3, and the fourth slice chip 110-4 are electrically connected through, for example, micro-bumps. Accordingly, signals and data are transmitted at high speed over the through-silicon vias between the base chip 100, the first slice chip 110-1, the second slice chip 110-2, the third slice chip 110-3, and the fourth slice chip 110-4.

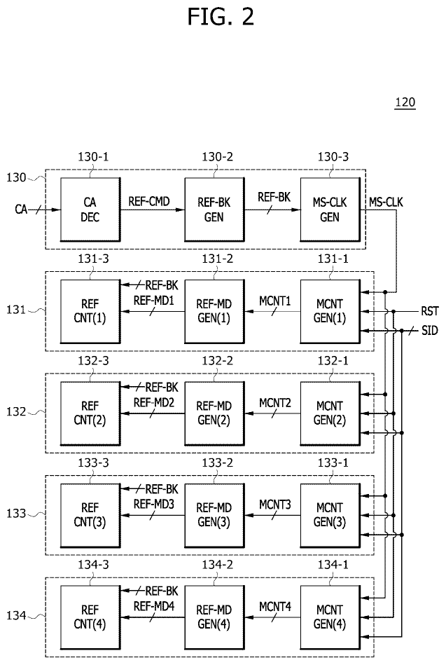

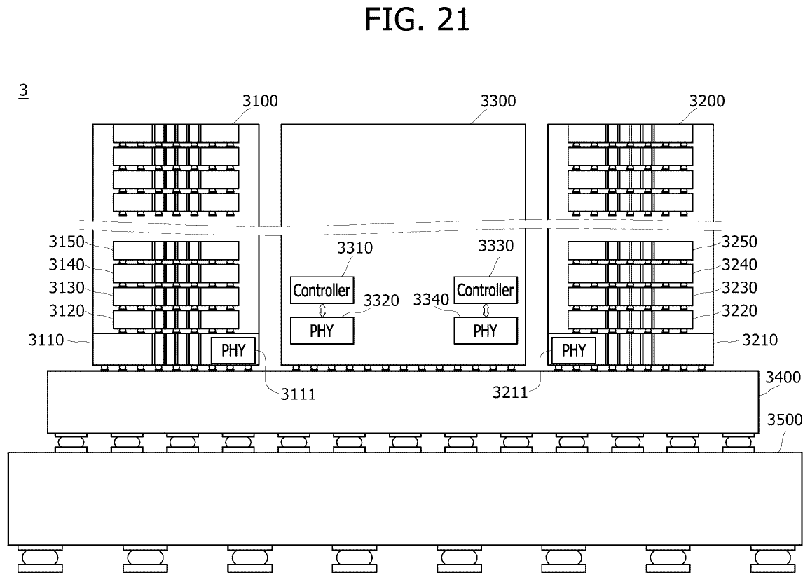

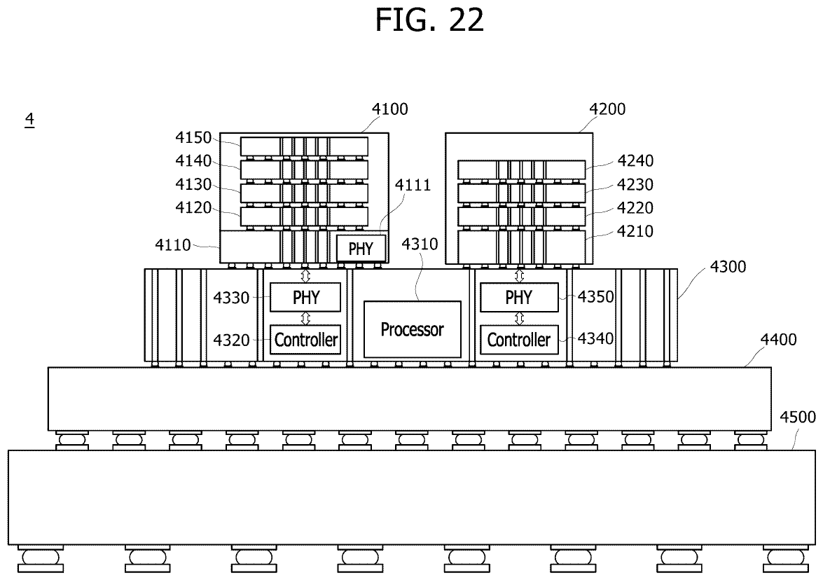

The base chip 100 includes a slice control circuit (SLICE CTR) 120. The slice control circuit 120 receives a command address CA from an external device (not shown). The external device may be implemented with a processor, for example, processor 3300 in FIG. 21 or processor 4310 in FIG. 22. The slice control circuit 120 sets, based on the command address CA, the refresh mode or process, for each of the first slice chip 110-1, the second slice chip 110-2, the third slice chip 110-3, and the fourth slice chip 110-4. For the sake of simplicity, “mode” as used herein include implementations of processes within a mode as well as not within a mode. The slice control circuit 120 controls the first slice chip 110-1, the second slice chip 110-2, the third slice chip 110-3, and the fourth slice chip 110-4 such that the refresh operation is performed according to the refresh mode of each of the first slice chip 110-1, the second slice chip 110-2, the third slice chip 110-3, and the fourth slice chip 110-4 at the time when a refresh bank signal is generated, for example, REF-BK in FIG. 2, that refreshes banks (not shown) included in the first slice chip 110-1, the second slice chip 110-2, the third slice chip 110-3, and the fourth slice chip 110-4. A bank refers to a logical or physical division of the memory cells in which an independent operation is performed in the first slice chip 110-1, the second slice chip 110-2, the third slice chip 110-3, and the fourth slice chip 110-4.

The slice control circuit 120 controls the first slice chip 110-1 such that refresh operations according to a first refresh mode, a second refresh mode, a third refresh mode, and a fourth refresh mode are sequentially and repeatedly performed at the time when the refresh bank signal is generated that refreshes banks included in the first slice chip 110-1. The first refresh mode is configured such that an auto-refresh operation for banks included in the first slice chip 110-1 is performed, and subsequently the auto-refresh operation for banks included in the first slice chip 110-1 is repeatedly performed. Thus, the auto-refresh operation for banks included in the first slice chip 110-1 is performed twice when the refresh bank signal that refreshes banks included in the first slice chip 110-1 is generated, for example, after an initialization operation of the stacked memory device 10. The second refresh mode is configured such that a smart refresh operation for banks included in the first slice chip 110-1 is performed when the refresh bank signal that refreshes banks included in the first slice chip 110-1 is generated, for example, after the first refresh mode. The smart refresh operation includes, for example, performing the refresh operation on word lines neighboring frequently accessed target word lines among the word lines connected to the bank included in the first slice chip 110-1. The third refresh mode is configured such that the auto-refresh operation for banks included in the first slice chip 110-1 is performed when the refresh bank signal that refreshes banks included in the first slice chip 110-1 is generated, for example, after the second refresh mode. The fourth refresh mode is configured such that the refresh operation for banks included in the first slice chip 110-1 is not performed or skipped when the refresh bank signal that refreshes banks included in the first slice chip 110-1 is generated, for example, after the third refresh mode.

The slice control circuit 120 controls the second slice chip 110-2 such that the refresh operations according to the second refresh mode, the third refresh mode, the fourth refresh mode, and the first refresh mode are sequentially and repeatedly performed at the time when the refresh bank signal is generated that refreshes banks included in the second slice chip 110-2. The second refresh mode is configured such that the smart refresh operation for banks included in the second slice chip 110-2 is performed when the refresh bank signal that refreshes banks included in the second slice chip 110-2 is generated, for example, after an initialization operation of the stacked memory device 10. The third refresh mode is configured such that the auto-refresh operation for banks included in the second slice chip 110-2 is performed when the refresh bank signal that refreshes banks included in the second slice chip 110-2 is generated, for example, after the second refresh mode. The fourth refresh mode is configured such that the refresh operation for banks included in the second slice chip 110-2 is not performed or skipped when the refresh bank signal that refreshes banks included in the second slice chip 110-2 is generated, for example, after the third refresh mode. The first refresh mode is configured such that the auto-refresh operation for banks included in the second slice chip 110-2 is performed twice when the refresh bank signal that refreshes banks included in the second slice chip 110-2 is generated, for example, after the fourth refresh mode.

The slice control circuit 120 controls the third slice chip 110-3 such that the refresh operations according to the third refresh mode, the fourth refresh mode, the first refresh mode, and the second refresh mode are sequentially and repeatedly performed at the time when the refresh bank signal is generated that refreshes banks included in the third slice chip 110-3. The third refresh mode is configured such that the auto-refresh operation for banks included in the third slice chip 110-3 is performed when the refresh bank signal that refreshes banks included in the third slice chip 110-3 is generated, for example, after an initialization operation of the stacked memory device 10. The fourth refresh mode is configured such that the refresh operation for banks included in the third slice chip 110-3 is not performed or skipped when the refresh bank signal that refreshes banks included in the third slice chip 110-3 is generated, for example, after the third refresh mode. The first refresh mode is configured such that the auto-refresh operation for banks included in the third slice chip 110-3 is performed twice when the refresh bank signal that refreshes banks included in the third slice chip 110-3 is generated, for example, after the fourth refresh mode. The second refresh mode is configured such that the smart refresh operation for banks included in the third slice chip 110-3 is performed when the refresh bank signal that refreshes banks included in the third slice chip 110-3 is generated, for example, after the first refresh mode.

The slice control circuit 120 controls the fourth slice chip 110-4 such that the refresh operations according to the fourth refresh mode, the first refresh mode, the second refresh mode, and the third refresh mode are sequentially and repeatedly performed at the time when the refresh bank signal is generated that refreshes banks included in the fourth slice chip 110-4. The fourth refresh mode is configured such that the refresh operation for banks included in the fourth slice chip 110-4 is not performed or skipped when the refresh bank signal that refreshes banks included in the fourth slice chip 110-4 is generated, for example, after an initialization operation of the stacked memory device 10. The first refresh mode is configured such that the auto-refresh operation for banks included in the fourth slice chip 110-4 is performed twice when the refresh bank signal that refreshes banks included in the fourth slice chip 110-4 is generated, for example, after the fourth refresh mode. The second refresh mode is configured such that the smart refresh operation for banks included in the fourth slice chip 110-4 is performed when the refresh bank signal that refreshes banks included in the fourth slice chip 110-4 is generated, for example, after the first refresh mode. The third refresh mode is configured such that the auto-refresh operation for banks included in the fourth slice chip 110-4 is performed when the refresh bank signal that refreshes banks included in the fourth slice chip 110-4 is generated, for example, after the second refresh mode.

FIG. 2 is a block diagram illustrating a slice control circuit 120 according to an embodiment of the present disclosure. As shown in FIG. 2, the slice control circuit 120 includes a mode selecting control circuit 130, a first slice refresh control circuit 131, a second slice refresh control circuit 132, a third slice refresh control circuit 133, and a fourth slice refresh control circuit 134.

The mode selecting control circuit 130 includes a command address decoder (CA DEC) 130-1, a refresh bank signal generation circuit (REF-BK GEN) 130-2, and a clock signal generation circuit (MS-CLK GEN) 130-3.

The command address decoder 130-1 decodes a command address CA to generate a refresh command REF-CMD for a refresh operation. The command address CA may include multiple bits, and bits of the bit sets included in the command address CA that generate the refresh command REF-CMD may vary depending on the embodiment. Although the refresh command REF-CMD is expressed as singular, the refresh command REF-CMD may include an all-bank refresh command for all-bank refresh and a per-bank refresh command for per-bank refresh depending on the embodiment. The all-bank refresh command is generated to simultaneously perform refresh operations for all banks included in each of the first slice chip 110-1, the second slice chip 110-2, the third slice chip 110-3, and the fourth slice chip 110-4. The per-bank refresh command is generated such that each bank included in each of the first slice chip 110-1, the second slice chip 110-2, the third slice chip 110-3, and the fourth slice chip 110-4 performs the refresh operation independent of other banks.

The refresh bank signal generation circuit 130-2 is connected to the command address decoder 130-1 to receive the refresh command REF-CMD from the command address decoder 130-1. The refresh bank signal generation circuit 130-2 generates, based on the refresh command REF-CMD, the refresh bank signal REF-BK that selects at least one bank on which the refresh operation is performed. The refresh bank signal generation circuit 130-2 generates, based on the refresh command REF-CMD, the refresh bank signal REF-BK that selects all banks simultaneously when the all-bank refresh operation is performed and generates the refresh bank signal REF-BK that sequentially selects each bank when the per-bank refresh operation is performed.

The clock signal generation circuit 130-3 is connected to the refresh bank signal generation circuit 130-2 to receive the refresh bank signal REF-BK from the refresh bank signal generation circuit 130-2. The clock signal generation circuit 130-3 generates a clock signal MS-CLK when the refresh bank signal REF-BK is generated that refreshes banks included in the first slice chip 110-1, the second slice chip 110-2, the third slice chip 110-3, and the fourth slice chip 110-4. In an example, each of the first slice chip 110-1, the second slice chip 110-2, the third slice chip 110-3, and the fourth slice chip 110-4 includes 16 banks, and the refresh bank signal REF-BK includes bit sets corresponding to the 16 banks. The clock signal generation circuit 130-3 receives the refresh bank signal REF-BK to generate the clock signal MS-CLK that toggles to select, for the refresh operation, the banks included in the first slice chip 110-1, the second slice chip 110-2, the third slice chip 110-3, and the fourth slice chip 110-4.

The first slice refresh control circuit 131 includes a first mode control signal generation circuit (MCNT GEN(1)) 131-1, a first refresh mode selecting signal generation circuit (REF-MD GEN(1)) 131-2, and a first refresh control circuit (REF CNT(1)) 131-3.

The first mode control signal generation circuit 131-1 is connected to the clock signal generation circuit 130-3 to receive the clock signal MS-CLK from the clock signal generation circuit 130-3. The first mode control signal generation circuit 131-1 generates a first mode control signal MCNT(1) based on the clock signal MS-CLK, a reset signal RST, and a slice ID SID. The first mode control signal generation circuit 131-1 generates the first mode control signal MCNT1 that controls the refresh operation performed on the first slice chip 110-1 during an initial refresh mode according to the slice ID SID when the reset signal RST is generated at a logic high level to begin an initialization operation of the stacked memory device 10. The reset signal RST and the slice ID SID may be supplied from outside of the stacked memory device 10 or may be generated inside the stacked memory device 10. The reset signal RST is generated at a predetermined logic high level for a short pulse or for an extended period of time, such as until refresh operations are completed. The predetermined logic high level of reset signal RST may be a logic high level or a logic low level to begin or trigger the initialization operation. The first mode control signal generation circuit 131-1 generates the first mode control signal MCNT1 that controls the refresh operation performed on the first slice chip 110-1 during a refresh mode that changes according to the slice ID SID at the time when the refresh bank signal REF-BK is generated that refreshes banks included in the first slice chip 110-1 and the clock signal MS-CLK is generated at a logic high level. For example, the first mode control signal generation circuit 131-1 generates the first mode control signal MCNT1 that controls the refresh operation performed on the first slice chip 110-1 during the first refresh mode, which is the initial refresh mode, according to the slice ID SID when the reset signal RST is generated and generates the first mode control signal MCNT1 to control the refresh operation performed repeatedly on the first slice chip 110-1 in the order of the second refresh mode, the third refresh mode, the fourth refresh mode, and the first refresh mode according to the slice ID SID at the time when the clock signal MS-CLK is generated at a logic high level.

The first refresh mode selecting signal generation circuit 131-2 is connected to the first mode control signal generation circuit 131-1 to receive the first mode control signal MCNT1 from the first mode control signal generation circuit 131-1. The first refresh mode selecting signal generation circuit 131-2 generates, based on the first mode control signal MCNT1, a first refresh mode selecting signal REF-MD1 that sets the refresh mode of the first slice chip 110-1. The first refresh mode selecting signal generation circuit 131-2 decodes the first mode control signal MCNT1 to generate the first refresh mode selecting signal REF-MD1 that sets the refresh mode of the first slice chip 110-1 according to the bits of the bit set included in the first mode control signal MCNT1. For example, the first refresh mode selecting signal generation circuit 131-2 generates the first refresh mode selecting signal REF-MD1 to control the refresh operation performed on the first slice chip 110-1 during the first refresh mode when the bits included in the first mode control signal MCNT1 are in a first bit set. For example, the first refresh mode selecting signal generation circuit 131-2 generates the first refresh mode selecting signal REF-MD1 to control the refresh operation performed on the first slice chip 110-1 during the second refresh mode when the bits included in the first mode control signal MCNT1 are in a second bit set. For example, the first refresh mode selecting signal generation circuit 131-2 generates the first refresh mode selecting signal REF-MD1 to control the refresh operation performed on the first slice chip 110-1 during the third refresh mode when the bits included in the first mode control signal MCNT1 are in a third bit set. For example, the first refresh mode selecting signal generation circuit 131-2 generates the first refresh mode selecting signal REF-MD1 to control the refresh operation performed on the first slice chip 110-1 during the fourth refresh mode when the bits included in the first mode control signal MCNT1 are in a fourth bit set.

The first refresh control circuit 131-3 is connected to the refresh bank signal generation circuit 130-2 and the first refresh mode selecting signal generation circuit 131-2 to receive the refresh bank signal REF-BK from the refresh bank signal generation circuit 130-2 and receive the first refresh mode selecting signal REF-MD1 from the first refresh mode selecting signal generation circuit 131-2. The first refresh control circuit 131-3 controls the first slice chip 110-1 such that the refresh operation is performed in the refresh mode based on the refresh bank signal REF-BK and the first refresh mode selecting signal REF-MD1. For example, the first refresh control circuit 131-3 controls the first slice chip 110-1 such that the auto-refresh operation is performed twice for banks included in the first slice chip 110-1 selected by the refresh bank signal REF-BK when the first refresh mode selecting signal REF-MD1 is received to control the refresh operation performed on the first slice chip 110-1 during the first refresh mode. For example, the first refresh control circuit 131-3 controls the first slice chip 110-1 such that the smart refresh operation is performed for banks included in the first slice chip 110-1 selected by the refresh bank signal REF-BK when the first refresh mode selecting signal REF-MD1 is received to control the refresh operation performed on the first slice chip 110-1 during the second refresh mode. For example, the first refresh control circuit 131-3 controls the first slice chip 110-1 such that the auto-refresh operation is performed for banks included in the first slice chip 110-1 selected by the refresh bank signal REF-BK when the first refresh mode selecting signal REF-MD1 is received to control the refresh operation performed on the first slice chip 110-1 during the third refresh mode. For example, the first refresh control circuit 131-3 controls the first slice chip 110-1 such that the refresh operation is not performed or skipped for banks included in the first slice chip 110-1 selected by the refresh bank signal REF-BK when the first refresh mode selecting signal REF-MD1 is received to control the refresh operation performed on the first slice chip 110-1 during the fourth refresh mode.

The second slice refresh control circuit 132 includes a second mode control signal generation circuit (MCNT GEN(2)) 132-1, a second refresh mode selecting signal generation circuit (REF-MD GEN(2)) 132-2, and a second refresh control circuit (REF CNT(2)) 132-3.

The second mode control signal generation circuit 132-1 is connected to the clock signal generation circuit 130-3 to receive the clock signal MS-CLK from the clock signal generation circuit 130-3. The second mode control signal generation circuit 132-1 generates a second mode control signal MCNT2 based on the clock signal MS-CLK, the reset signal RST, and the slice ID SID. The second mode control signal generation circuit 132-1 generates the second mode control signal MCNT2 to control the refresh operation performed on the second slice chip 110-2 during an initial refresh mode according to the slice ID SID when the reset signal RST is generated at a logic high level to begin the initialization operation of the stacked memory device 10. The second mode control signal generation circuit 132-1 generates the second mode control signal MCNT2 to control the refresh operation performed on the second slice chip 110-2 during a refresh mode that changes according to the slice ID SID at the time when the refresh bank signal that refreshes banks included in the second slice chip 110-2 is generated and the clock signal MS-CLK is generated at a logic high level. For example, the second mode control signal generation circuit 132-1 generates the second mode control signal MCNT2 to control the refresh operation performed on the second slice chip 110-2 during the second refresh mode, which is the initial refresh mode, according to the slice ID SID when the reset signal RST is generated and generates the second mode control signal MCNT2 to control the refresh operation repeatedly performed on the second slice chip 110-2 in the order of the third refresh mode, the fourth refresh mode, the first refresh mode, and the second refresh mode according to the slice ID SID at the time when the clock signal MS-CLK is generated at a logic high level.

The second refresh mode selecting signal generation circuit 132-2 is connected to the second mode control signal generation circuit 132-1 to receive the second mode control signal MCNT2 from the second mode control signal generation circuit 132-1. The second refresh mode selecting signal generation circuit 132-2 generates, based on the second mode control signal MCNT2, a second refresh mode selecting signal REF-MD2 that sets the refresh mode of the second slice chip 110-2. The second refresh mode selecting signal generation circuit 132-2 decodes the second mode control signal MCNT2 to generate the second refresh mode selecting signal REF-MD2 that sets the refresh mode of the second slice chip 110-2 according to the bits of the bit set included in the second mode control signal MCNT2. For example, the second refresh mode selecting signal generation circuit 132-2 generates the second refresh mode selecting signal REF-MD2 to control the refresh operation performed on the second slice chip 110-2 during the second refresh mode when the bits included in the second mode control signal MCNT2 are in the second bit set. For example, the second refresh mode selecting signal generation circuit 132-2 generates the second refresh mode selecting signal REF-MD2 to control the refresh operation performed on the second slice chip 110-2 during the third refresh mode when the bits included in the second mode control signal MCNT2 are in the third bit set. For example, the second refresh mode selecting signal generation circuit 132-2 generates the second refresh mode selecting signal REF-MD2 to control the refresh operation performed on the second slice chip 110-2 during the fourth refresh mode when the bits included in the second mode control signal MCNT2 are in the fourth bit set. For example, the second refresh mode selecting signal generation circuit 132-2 generates the second refresh mode selecting signal REF-MD2 to control the refresh operation performed on the second slice chip 110-2 during the first refresh mode when the bits included in the second mode control signal MCNT2 are in the first bit set.

The second refresh control circuit 132-3 is connected to the refresh bank signal generation circuit 130-2 and the second refresh mode selecting signal generation circuit 132-2 to receive the refresh bank signal REF-BK from the refresh bank signal generation circuit 130-2 and receive the second refresh mode selecting signal REF-MD2 from the second refresh mode selecting signal generation circuit 132-2. The second refresh control circuit 132-3 controls the second slice chip 110-2 such that the refresh operation is performed in the refresh mode based on the refresh bank signal REF-BK and the second refresh mode selecting signal REF-MD2. For example, the second refresh control circuit 132-3 controls the second slice chip 110-2 such that the smart refresh operation is performed for banks included in the second slice chip 110-2 selected by the refresh bank signal REF-BK when the second refresh mode selecting signal REF-MD2 is received to control the refresh operation performed on the second slice chip 110-2 during the second refresh mode. For example, the second refresh control circuit 132-3 controls the second slice chip 110-2 such that the auto-refresh operation is performed for banks included in the second slice chip 110-2 selected by the refresh bank signal REF-BK when the second refresh mode selecting signal REF-MD2 is received to control the refresh operation performed on the second slice chip 110-2 during the third refresh mode. For example, the second refresh control circuit 132-3 controls the second slice chip 110-2 such that the refresh operation is not performed or skipped for banks included in the second slice chip 110-2 selected by the refresh bank signal REF-BK when the second refresh mode selecting signal REF-MD2 is received to control the refresh operation performed on the second slice chip 110-2 during the fourth refresh mode. For example, the second refresh control circuit 132-3 controls the second slice chip 110-2 such that the auto-refresh operation is performed twice for banks included in the second slice chip 110-2 selected by the refresh bank signal REF-BK when the second refresh mode selecting signal REF-MD2 is received to control the refresh operation performed on the second slice chip 110-2 during the first refresh mode.

The third slice refresh control circuit 133 includes a third mode control signal generation circuit (MCNT GEN(3)) 133-1, a third refresh mode selecting signal generation circuit (REF-MD GEN(3)) 133-2, and a third refresh control circuit (REF-CNT(3)) 133-3.

The third mode control signal generation circuit 133-1 is connected to the clock signal generation circuit 130-3 to receive the clock signal MS-CLK from the clock signal generation circuit 130-3. The third mode control signal generation circuit 133-1 generates a third mode control signal MCNT3 based on the clock signal MS-CLK, the reset signal RST, and the slice ID SID. The third mode control signal generation circuit 133-1 generates the third mode control signal MCNT3 to control the refresh operation performed on the third slice chip 110-3 during the initial refresh mode according to the slice ID SID when the reset signal RST is generated at a logic high level to begin an initialization operation of the stacked memory device 10. The third mode control signal generation circuit 133-1 generates the third mode control signal MCNT3 to control the refresh operation performed on the third slice chip 110-3 during the refresh mode that changes according to the slice ID SID at the time when the refresh bank signal that refreshes banks included in the third slice chip 110-3 is generated and the clock signal MS-CLK is generated at a logic high level. For example, the third mode control signal generation circuit 133-1 generates the third mode control signal MCNT3 to control the refresh operation performed on the third slice chip 110-3 during the third refresh mode, which is the initial refresh mode, according to the slice ID SID when the reset signal RST is generated and generates the third mode control signal MCNT3 to control the refresh operation repeatedly performed on the third slice chip 110-3 in the order of the fourth refresh mode, the first refresh mode, the second refresh mode, and the third refresh mode according to the slice ID SID at the time when the clock signal MS-CLK is generated at a logic high level.

The third refresh mode selecting signal generation circuit 133-2 is connected to the third mode control signal generation circuit 133-1 to receive the third mode control signal MCNT3 from the third mode control signal generation circuit 133-1. The third refresh mode selecting signal generation circuit 133-2 generates, based on the third mode control signal MCNT3, a third refresh mode selecting signal REF-MD3 that sets the refresh mode of the third slice chip 110-3. The third refresh mode selecting signal generation circuit 133-2 decodes the third mode control signal MCNT3 to generate the third refresh mode selecting signal REF-MD3 that sets the refresh mode of the third slice chip 110-3 according to the bits of the bit set included in the third mode control signal MCNT3. For example, the third refresh mode selecting signal generation circuit 133-2 generates the third refresh mode selecting signal REF-MD3 that controls the refresh operation performed on the third slice chip 110-3 during the third refresh mode when the bits included in the third mode control signal MCNT3 are in the third bit set. For example, the third refresh mode selecting signal generation circuit 133-2 generates the third refresh mode selecting signal REF-MD3 that controls the refresh operation performed on the third slice chip 110-3 during the fourth refresh mode when the bits included in the third mode control signal MCNT3 are in the fourth bit set. For example, the third refresh mode selecting signal generation circuit 133-2 generates the third refresh mode selecting signal REF-MD3 that controls the refresh operation performed on the third slice chip 110-3 during the first refresh mode when the bits included in the third mode control signal MCNT3 are in the first bit set. For example, the third refresh mode selecting signal generation circuit 133-2 generates the third refresh mode selecting signal REF-MD3 that controls the refresh operation performed on the third slice chip 110-3 during the second refresh mode when the bits included in the third mode control signal MCNT3 are in the second bit set.

The third refresh control circuit 133-3 is connected to the refresh bank signal generation circuit 130-2 and the third refresh mode selecting signal generation circuit 133-2 to receive the refresh bank signal REF-BK from the refresh bank signal generation circuit 130-2, and receive the third refresh mode selecting signal REF-MD3 from the third refresh mode selecting signal generation circuit 133-2. The third refresh control circuit 133-3 controls the third slice chip 110-3 such that the refresh operation is performed in the refresh mode based on the refresh bank signal REF-BK and the third refresh mode selecting signal REF-MD3. For example, the third refresh control circuit 133-3 controls the third slice chip 110-3 such that the auto-refresh operation is performed for banks included in the third slice chip 110-3 selected by the refresh bank signal REF-BK when the third refresh mode selecting signal REF-MD3 is received to control the refresh operation performed on the third slice chip 110-3 during the third refresh mode. For example, the third refresh control circuit 133-3 controls the third slice chip 110-3 such that the refresh operation for banks included in the third slice chip 110-3 selected by the refresh bank signal REF-BK is not performed or skipped when the third refresh mode selecting signal REF-MD3 is received to control the refresh operation performed on the third slice chip 110-3 during the fourth refresh mode. For example, the third refresh control circuit 133-3 controls the third slice chip 110-3 such that the auto-refresh operation is performed twice for banks included in the third slice chip 110-3 selected by the refresh bank signal REF-BK when the third refresh mode selecting signal REF-MD3 is received to control the refresh operation performed on the third slice chip 110-3 during the first refresh mode. For example, the third refresh control circuit 133-3 controls the third slice chip 110-3 such that the smart-refresh operation is performed for banks included in the third slice chip 110-3 selected by the refresh bank signal REF-BK when the third refresh mode selecting signal REF-MD3 is received to control the refresh operation performed on the third slice chip 110-3 during the second refresh mode.

The fourth slice refresh control circuit 134 includes a fourth mode control signal generation circuit (MCNT GEN(4)) 134-1, a fourth refresh mode selecting signal generation circuit (REF-MD GEN(4)) 134-2, and a fourth refresh control circuit (REF CNT(4)) 134-3.

The fourth mode control signal generation circuit 134-1 is connected to the clock signal generation circuit 130-3 to receive the clock signal MS-CLK from the clock signal generation circuit 130-3. The fourth mode control signal generation circuit 134-1 generates a fourth mode control signal MCNT4 based on the clock signal MS-CLK, the reset signal RST, and the slice ID SID. The fourth mode control signal generation circuit 134-1 generates the fourth mode control signal MCNT4 to control the refresh operation performed on the fourth slice chip 110-4 during the initial refresh mode according to the slice ID SID when the reset signal RST is generated at a logic high level to begin the initialization operation of the stacked memory device 10. The fourth mode control signal generation circuit 134-1 generates the fourth mode control signal MCNT4 to control the refresh operation performed on the fourth slice chip 110-4 during the refresh mode that changes according to the slice ID SID at the time when the refresh bank signal REF-BK that refreshes banks included in the fourth slice chip 110-4 is generated and the clock MS-CLK is generated at a logic high level. For example, the fourth mode control signal generation circuit 134-1 generates the fourth mode control signal MCNT4 to control the refresh operation performed on the fourth slice chip 110-4 during the fourth refresh mode, which is the initial refresh mode, according to the slice ID SID when the reset signal RST is generated and generates the fourth mode control signal MCNT4 to control the refresh operation repeatedly performed on the fourth slice chip 110-4 in the order of the first refresh mode, the second refresh mode, the third refresh mode, and the fourth refresh mode according to the slice ID SID at the time when the clock signal MS-CLK is generated at a logic high level.

The fourth refresh mode selecting signal generation circuit 134-2 is connected to the fourth mode control signal generation circuit 134-1 to receive the fourth mode control signal MCNT4 from the fourth mode control signal generation circuit 134-1. The fourth refresh mode selecting signal generation circuit 134-2 generates, based on the fourth mode control signal MCNT4, a fourth refresh mode selecting signal REF-MD4 that sets the refresh mode of the fourth slice chip 110-4. The fourth refresh mode selecting signal generation circuit 134-2 decodes the fourth mode control signal MCNT4 to generate the fourth refresh mode selecting signal REF-MD4 that sets the refresh mode of the fourth slice chip 110-4 according to the bits of the bit set included in the fourth mode control signal MCNT4. For example, the fourth refresh mode selecting signal generation circuit 134-2 generates the fourth refresh mode selecting signal REF-MD4 to control the refresh operation performed on the fourth slice chip 110-4 during the fourth refresh mode when the bits included in the fourth mode control signal MCNT4 are in the fourth bit set. For example, the fourth refresh mode selecting signal generation circuit 134-2 generates the fourth refresh mode selecting signal REF-MD4 to control the refresh operation performed on the fourth slice chip 110-4 during the first refresh mode when the bits included in the fourth mode control signal MCNT4 are in the first bit set. For example, the fourth refresh mode selecting signal generation circuit 134-2 generates the fourth refresh mode selecting signal REF-MD4 to control the refresh operation performed on the fourth slice chip 110-4 during the second refresh mode when the bits included in the fourth mode control signal MCNT4 are in the second bit set. For example, the fourth refresh mode selecting signal generation circuit 134-2 generates the fourth refresh mode selecting signal REF-MD4 to control the refresh operation performed on the fourth slice chip 110-4 during the third refresh mode when the bits included in the fourth mode control signal MCNT4 are in the third bit set.

The fourth refresh control circuit 134-3 is connected to the refresh bank signal generation circuit 130-2 and the fourth refresh mode selecting signal generation circuit 134-2 to receive the refresh bank signal REF-BK from the refresh bank signal generation circuit 130-2 and receive the fourth refresh mode selecting signal REF-MD4 from the fourth refresh mode selecting signal generation circuit 134-2. The fourth refresh control circuit 134-3 controls the fourth slice chip 110-4 such that the refresh operation is performed in the refresh mode based on the refresh bank signal REF-BK and the fourth refresh mode selecting signal REF-MD4. For example, the fourth refresh control circuit 134-3 controls the fourth slice chip 110-4 such that the refresh operation for banks included in the fourth slice chip 110-4 selected by the refresh bank signal REF-BK is not performed or skipped when the fourth refresh mode selecting signal REF-MD4 is received to control the refresh operation performed on the fourth slice chip 110-4 during the fourth refresh mode. For example, the fourth refresh control circuit 134-3 controls the fourth slice chip 110-4 such that the auto-refresh operation is performed twice for banks included in the fourth slice chip 110-4 selected by the refresh bank signal REF-BK when the fourth refresh mode selecting signal REF-MD4 is received to control the refresh operation performed on the fourth slice chip 110-4 during the first refresh mode. For example, the fourth refresh control circuit 134-3 controls the fourth slice chip 110-4 such =that the smart refresh operation is performed for banks included in the fourth slice chip 110-4 selected by the refresh bank signal REF-BK when the fourth refresh mode selecting signal REF-MD4 is received to control the refresh operation performed on the fourth slice chip 110-4 during the second refresh mode. For example, the fourth refresh control circuit 134-3 controls the fourth slice chip 110-4 such that the auto-refresh operation is performed for banks included in the fourth slice chip 110-4 selected by the refresh bank signal REF-BK when the fourth refresh mode selecting signal REF-MD4 is received to control the refresh operation performed on the fourth slice chip 110-4 during the third refresh mode.

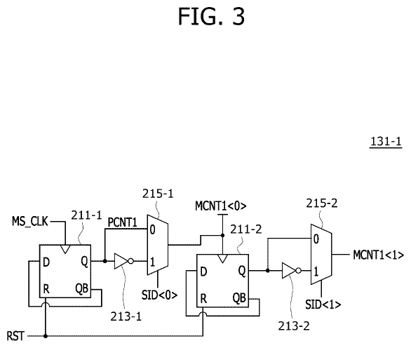

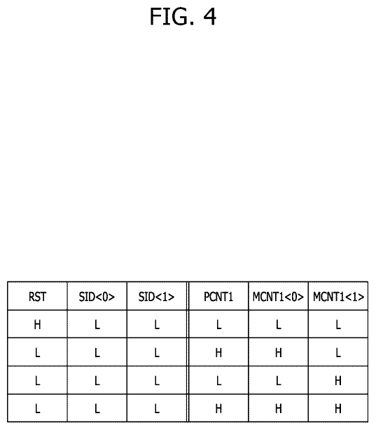

FIG. 3 is a circuit diagram illustrating a first mode control signal generation circuit 131-1 according to an embodiment of the present disclosure, and FIG. 4 is a table including data during operation of the first mode control signal generation circuit 131-1.

As shown in FIG. 3, the first mode control signal generation circuit 131-1 includes flip-flops 211-1 and 211-2, inverters 213-1 and 213-2, and selectors 215-1 and 215-2. The flip-flop 211-1 outputs a first pre-control signal PCNT1 through output terminal Q at a logic low level when the reset signal RST is generated at a logic high level to begin an initialization operation. The flip-flop 211-1 receives and latches a signal from inverted output terminal QB as feedback through input terminal D and outputs the signal from inverted output terminal QB through output terminal Q at the time when the refresh bank signal that refreshes banks included in the first slice chip 110-1 is generated and the clock signal MS-CLK is generated at a logic high level following and preceding a logic low level, such as a pulse, hereinafter referred to as “clock signal MS-CLK toggles”. The flip-flop 211-1 inverts the logic level of the first pre-control signal PCNT1 when the refresh bank signal that refreshes banks included in the first slice chip 110-1 is generated and the clock signal MS-CLK toggles. The inverter 213-1 inversely buffers the first pre-control signal PCNT1 to output an inversely buffered signal of the first pre-control signal PCNT1. The selector 215-1 outputs the first pre-control signal PCNT1 or an output signal of the inverter 213-1 as a first bit MCNT1<0> of the first mode control signal according to a first bit SID<0> of the slice ID. To select the refresh mode of the first slice chip 110-1, the selector 215-1 outputs the first pre-control signal PCNT1 as the first bit MCNT1<0> of the first mode control signal according to the first bit SID<0> of the slice ID at a logic low level. The flip-flop 211-2 outputs the signal output through output terminal Q at a logic low level when the reset signal RST is generated at a logic high level to begin the initialization operation. The flip-flop 211-2 receives and latches the signal from inverting output terminal QB as feedback through input terminal D and outputs the signal from inverting output terminal QB through output terminal Q at the time when the first bit MCNT1<0> of the first mode control signal is generated at a logic high level. Thus, the flip-flop 211-2 inverts the logic level of output terminal Q at the time when the first bit MCNT1<0> of the first mode control signal is generated at a logic high level. The inverter 213-2 inversely buffers an output signal of the flip-flop 211-2 to output an inversely buffered signal from the output of the flip-flop 211-2. The selector 215-2 outputs the output signal of the flip-flop 211-2 or an output signal of the inverter 213-2 as a second bit MCNT1<1> of the first mode control signal according to a second bit SID<1> of the slice ID. To select the refresh mode of the first slice chip 110-1, the selector 215-2 outputs the output signal of the flip-flop 211-2 as a second bit MCNT1<1> of the first mode control signal according to a second bit SID<1> of the slice ID.

Operation of the first mode control signal generation circuit 131-1 is described with reference to FIG. 3 and FIG. 4. When the first bit SID<0> of the slice ID and the second bit SID<1> of the slice ID are at a logic low level to select the refresh mode of the first slice chip 110-1, operation of the first mode control signal generation circuit 131-1 is performed.

As shown in FIG. 3 and a first data row in FIG. 4, when the reset signal RST is generated at a logic high level H to begin the initialization operation, the flip-flop 211-1 outputs the first pre-control signal PCNT1 at a logic low level L, the selector 215-1 outputs the first bit MCNT1<0> of the first mode control signal at a logic low level L according to the first bit SID<0> of the slice ID at a logic low level L, and the selector 215-2 outputs the second bit MCNT1<1> of the first mode control signal at a logic low level L according to the second bit SID<1> of the slice ID at a logic low level L.

As shown in FIG. 3 and a second data row in FIG. 4, after the initialization operation, when a refresh bank signal that refreshes banks included in the first slice chip 110-1 is generated and the clock signal MS-CLK toggles for a first time, the flip-flop 211-1 outputs the first pre-control signal PCNT1 at a logic high level H, the selector 215-1 outputs the first bit MCNT1<0> of the first mode control signal at a logic high level H according to the first bit SID<0> of the slice ID at a logic low level L, and the selector 215-2 outputs the second bit MCNT1<1> of the first mode control signal at a logic low level L according to the second bit SID<1> of the slice ID at a logic low level L.

As shown in FIG. 3 and a third data row in FIG. 4, when the refresh bank signal that refreshes banks included in the first slice chip 110-1 is generated and the clock signal MS-CLK toggles for a second time, the flip-flop 211-1 outputs the first pre-control signal PCNT1 at a logic low level L, the selector 215-1 outputs the first bit MCNT1<0> of the first mode control signal at a logic low level L according to the first bit SID<0> of the slice ID at a logic low level L, and the selector 215-2 outputs the second bit MCNT1<1> of the first mode control signal at a logic high level H according to the second bit SID<1> of the slice ID at a logic low level L.

As shown in FIG. 3 and a fourth data row in FIG. 4, when the refresh bank signal that refreshes banks included in the first slice chip 110-1 is generated and the clock signal MS-CLK toggles for a third time, the flip-flop 211-1 outputs the first pre-control signal PCNT1 at a logic high level ‘H, the selector 215-1 outputs the first bit MCNT1<0> of the first mode control signal at a logic high level H according to the first bit SID<0> of the slice ID set at a logic low level L, and the selector 215-2 outputs the second bit MCNT1<1> of the first mode control signal at a logic high level H according to the second bit SID<1> of the slice ID at a logic low level L.

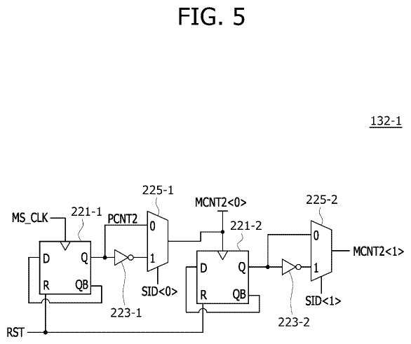

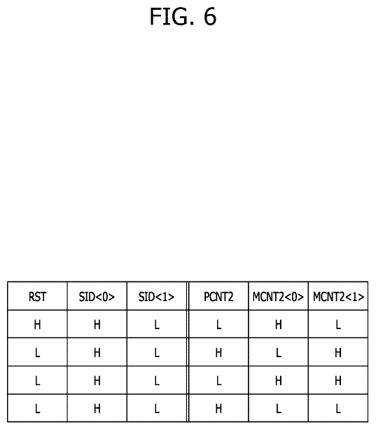

FIG. 5 is a circuit diagram illustrating a second mode control signal generation circuit 132-1 according to an embodiment of the present disclosure, and FIG. 6 is a table including data during operation of the second mode control signal generation circuit 132-1 according to an embodiment of the present disclosure.

As shown in FIG. 5, the second mode control signal generation circuit 132-1 includes flip-flops 221-1 and 221-2, inverters 223-1 and 223-2, and selectors 225-1 and 225-2. The flip-flop 221-1 outputs a second pre-control signal PCNT2 through output terminal Q at a logic low level when the reset signal RST is generated at a logic high level to begin an initialization operation. The flip-flop 221-1 receives and latches the signal from inverting output terminal QB as feedback through input terminal D and outputs the signal from inverting output terminal QB through output terminal Q at the time when the refresh bank signal that refreshes banks included in the second slice chip 110-2 is generated and the clock signal MS-CLK toggles. Thus, the flip-flop 221-1 inverts the logic level of the second pre-control signal PCNT2 when the refresh bank signal that refreshes banks included in the second slice chip 110-2 is generated and the clock signal MS-CLK toggles. The inverter 223-1 inversely buffers the second pre-control signal PCNT2 to output an inversely buffered signal of the second pre-control signal PCNT2. The selector 225-1 outputs the second pre-control signal PCNT2 or an output signal of the inverter 223-1 as a first bit MCNT2<0> of the second mode control signal according to the first bit SID<0> of the slice ID. To select the refresh mode of the second slice chip 110-2, the selector 225-1 outputs the output signal of the inverter 223-1 as the first bit MCNT2<0> of the second mode control signal according to the first bit SID<0> of the slice ID. The flip-flop 221-2 outputs the signal output through output terminal Q at a logic low level when the reset signal RST is generated at a logic high level to begin the initialization operation. The flip-flop 221-2 receives and latches the signal from inverting output terminal QB as feedback through input terminal D and outputs the signal from inverting output terminal QB through output terminal Q at the time when the first bit MCNT2<0> of the second mode control signal MCNT2 is generated at a logic high level. Thus, the flip-flop 221-2 inverts the logic level of output terminal Q at the time when the first bit MCNT2<0> of the second mode control signal MCNT2 is generated at a logic high level. The inverter 223-2 inversely buffers the output signal of the flip-flop 221-2 to output an inversely buffered signal from the output of the flip-flop 221-2. The selector 225-2 outputs the output signal of the flip-flop 221-2 or the output signal of the inverter 223-2 as the second bit MCNT2<1> of the second mode control signal according to the second bit SID<1> of the slice ID. To select the refresh mode of the second slice chip 110-2, the selector 225-2 outputs the output signal of the flip-flop 221-2 as the second bit MCNT2<1> of the second mode control signal according to the second bit SID<1> of the slice ID.

Operation of the second mode control signal generation circuit 132-1 is described with reference to FIG. 5 and FIG. 6. When the first bit SID<0> of the slice ID is at a logic high level and the first bit SID<1> of the slice ID is at a logic low level to select the refresh mode of the second slice chip 110-2, operation of the second mode control signal generation circuit 132-1 is performed.

As shown in FIG. 5 and a first data row in FIG. 6, when the reset signal RST is generated at a logic high level H to begin the initialization operation, the flip-flop 221-1 outputs the second pre-control signal PCNT2 at a logic low level L, the selector 225-1 outputs the first bit MCNT2<0> of the second mode control signal at a logic high level H according to the first bit SID<0> of the slice ID at a logic high level H, and the selector 225-2 outputs the second bit MCNT2<1> of the second mode control signal at a logic low level L according to the second bit SID<1> of the slice ID at a logic low level L.

As shown in FIG. 5 and a second data row in FIG. 6, after the initialization operation, when the refresh bank signal is generated that refreshes banks included in the second slice chip 110-2 and the clock signal MS-CLK toggles for a first time after the initialization operation, the flip-flop 221-1 outputs the second pre-control signal PCNT2 at a logic high level H, the selector 225-1 outputs the first bit MCNT2<0> of the second mode control signal at a logic low level L according to the first bit SID<0> of the slice ID at a logic high level H, and the selector 225-2 outputs the second bit MCNT<1> of the second mode control signal at a logic high level H according to the second bit SID<1> of the slice ID at a logic low level L.

As shown in FIG. 5 and a third data row in FIG. 6, when the refresh bank signal is generated that refreshes banks included in the second slice chip 110-2 and the clock signal MS-CLK toggles for a second time, the flip-flop 221-1 outputs the second pre-control signal PCNT2 at a logic low level L, the selector 225-1 outputs the first bit MCNT2<0> of the second mode control signal of a logic high level H according to the first bit SID<0> of the slice ID at a logic high level H, and the selector 225-2 outputs the second bit MCNT<1> of the second mode control signal at a logic high level H according to the second bit SID<1> of the slice ID at a logic low level L.

As shown in FIG. 5 and a fourth data row in FIG. 6, when the refresh bank signal is generated that refreshes banks included in the second slice chip 110-2 and the clock signal MS-CLK toggles for a third time, the flip-flop 221-1 outputs the second pre-control signal PCNT2 at a logic high level H, the selector 225-1 outputs the first bit MCNT2<0> of the second mode control signal at a logic low level L according to the first bit SID<0> of the slice ID at a logic high level H, and the selector 225-2 outputs the second bit MCNT<1> of the second mode control signal at a logic low level L according to the second bit SID<1> of the slice ID at a logic low level L.

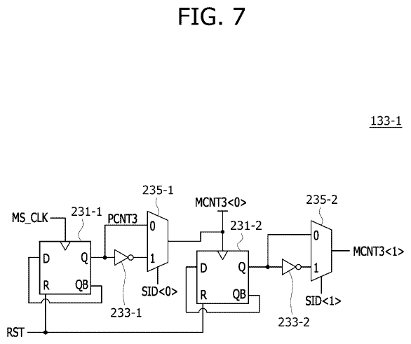

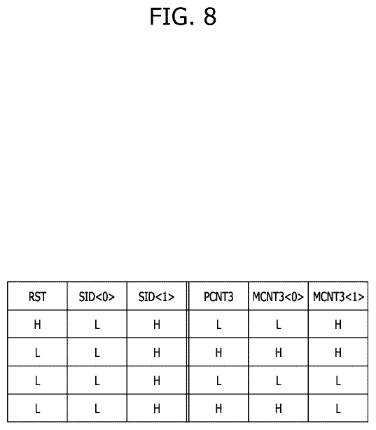

FIG. 7 is a circuit diagram illustrating a third mode control signal generation circuit 133-1 according to an embodiment of the present disclosure, and FIG. 8 is a table including data during operation of the third mode control signal generation circuit 133-1 according to an embodiment of the present disclosure.

As shown in FIG. 7, the third mode control signal generation circuit 133-1 includes flip-flops 231-1 and 231-2, inverters 233-1 and 233-2, and selectors 235-1 and 235-2. The flip-flop 231-1 outputs a third pre-control signal PCNT3 through output terminal Q when the reset signal RST is generated at a logic high level to begin an initialization operation. The flip-flop 231-1 receives and latches a signal from inverting output terminal QB as feedback and outputs the signal from inverting output terminal QB through the output terminal Q at the time when a refresh bank signal is generated that refreshes banks included in the third slice chip 110-3 and the clock signal MS-CLK toggles. Thus, the flip-flop 231-1 inverts the logic level of the third pre-control signal PCNT3 when the refresh bank signal that refreshes banks included in the third slice chip 110-3 is generated and the clock signal MS-CLK toggles. The inverter 233-1 inversely buffers the third pre-control signal PCNT3 to output an inversely buffered signal of the third pre-control signal PCNT3. The selector 235-1 outputs the third pre-control signal PCNT3 or an output signal of the inverter 233-1 as a first bit MCNT3<0> of the third mode control signal according to the first bit SID<0> of the slice ID. To select the refresh mode of the third slice chip 110-3, the selector 235-1 outputs the third pre-control signal PCNT3 as the first bit MCNT3<0> of the third mode control signal according to the first bit SID<0> of the slice ID at a logic low level. The flip-flop 231-2 outputs the signal through output terminal Q at a logic low level when the reset signal RST is generated at a logic high level to begin the initialization operation. The flip-flop 231-2 receives and latches the signal from inverting output terminal QB and outputs the signal from inverting output terminal QB through output terminal Q at the time when the first bit MCNT3<0> of the third mode control signal is generated at a logic high level. Thus, the flip-flop 231-2 inverts the logic level of output terminal Q at the time when the first bit MCNT3<0> of the third mode control signal is generated at a logic high level. The inverter 233-2 inversely buffers the output signal of the flip-flop 231-2 to output an inversely buffered signal from the output of the flip-flop 231-2. The selector 235-2 outputs the output signal of the flip-flop 231-1 or the output signal of the inverter 233-2 as a second bit MCNT3<1> of the third mode control signal according to the second bit SID<1> of the slice ID.

Operation of the third mode control signal generation circuit 133-1 is described with reference to FIG. 7 and FIG. 8. When the first bit SID<0> of the slice ID is at a logic low level and the second bit SID<1> of the slice ID is at a logic high level to select the refresh mode of the third slice chip 110-3, operation of the third mode control signal generation circuit 133-1 is performed.

As shown in FIG. 7 and a first data row in FIG. 8, when the reset signal RST is generated at a logic high level to begin the initialization operation, the flip-flop 231-1 outputs the third pre-control signal PCNT3 at a logic low level L, the selector 235-1 outputs the first bit MCNT3<0> of the third mode control signal at a logic low level L according to the first bit SID<0> of the slice ID at a logic low level L, and the selector 235-2 outputs the second bit MCNT3<1> of the third mode control signal of a logic high level H according to the second bit SID<1> of the slice ID at a logic high level H.

As shown in FIG. 7 and a second data row in FIG. 8, after the initialization operation, when the refresh bank signal is generated that refreshes banks included in the third slice chip 110-3 and the clock signal MS-CLK toggles for a first time, the flip-flop 231-1 outputs the third pre-control signal PCNT3 at a logic high level H, the selector 235-1 outputs the first bit MCNT3<0> of the third mode control signal at a logic high level H according to the first bit SID<0> of the slice ID at a logic low level L, and the selector 235-2 outputs the second bit MCNT3<1> of the third mode control signal of a logic high level H according to the second bit SID<1> of the slice ID at a logic high level H.

As shown in FIG. 7 and a third data row in FIG. 8, when the refresh bank signal is generated that refreshes banks included in the third slice chip 110-3 and the clock signal MS-CLK toggles for a second time, the flip-flop 231-1 outputs the third pre-control signal PCNT3 at a logic low level L, the selector 235-1 outputs the first bit MCNT3<0> of the third mode control signal at a logic low level L according to the first bit SID<0> of the slice ID at a logic low level L, and the selector 235-2 outputs the second bit MCNT3<1> of the third mode control signal MCNT3 at a logic low level L according to the second bit SID<1> of the slice ID at a logic high level H.

As shown in FIG. 7 and a fourth data row in FIG. 8, when the refresh bank signal is generated that refreshes banks included in the third slice chip 110-3 and the clock signal MS-CLK toggles for a third time, the flip-flop 231-1 outputs the third pre-control signal PCNT3 at a logic high level H, the selector 235-1 outputs the first bit MCNT3<0> of the third mode control signal at a logic high level H according to the first bit SID<0> of the slice ID at a logic low level L, and the selector 235-2 outputs the second bit MCNT3<1> of the third mode control signal at a logic low level L according to the second bit SID<1> of the slice ID at a logic high level H.

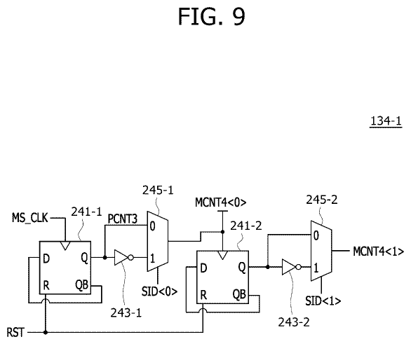

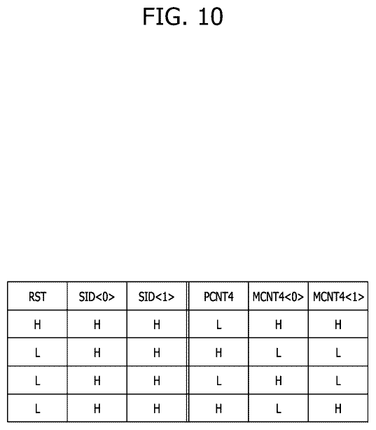

FIG. 9 is a circuit diagram illustrating a fourth mode control signal generation circuit 134-1 according to an embodiment of the present disclosure, and FIG. 10 is a table including data during operation of the fourth mode control signal generation circuit 134-1 according to an embodiment of the present disclosure.

As shown in FIG. 9, the fourth mode control signal generation circuit 134-1 includes flip-flops 241-1 and 241-2, inverters 243-1 and 243-2, and selectors 245-1 and 245-2. The flip-flop 241-1 outputs a fourth pre-control signal PCNT4 through output terminal Q at a logic low level when a reset signal RST is generated at a logic high level to begin an initialization operation. The flip-flop 241-1 receives and latches a signal from inverting output terminal QB as feedback through input terminal D and outputs the signal from inverting output terminal QB through output terminal Q at the time when the refresh bank signal that refreshes banks included in the fourth slice chip 110-4 is generated and the clock signal MS-CLK toggles. Thus, the flip-flop 241-1 inverts the logic level of the fourth pre-control signal PCMT4 when the refresh bank signal that refreshes banks included in the fourth slice chip 110-4 is generated and the clock signal MS-CLK toggles. The inverter 243-1 inversely buffers the fourth pre-control signal PCNT4 to output an inversely buffered signal of the fourth pre-control signal PCNT4. The selector 245-1 outputs the fourth pre-control signal PCNT4 or an output signal of the inverter 243-1 as a first bit MCNT4<0> of the fourth mode control signal according to the first bit SID<0> of the slice ID. To select the refresh mode of the fourth slice chip 110-4, the selector 245-1 outputs the output signal of the inverter 243-1 as the first bit MCNT4<0> of the fourth mode control signal according to the first bit SID<0> of the slice ID at a logic low level. The flip-flop 241-2 outputs the signal output through output terminal Q at a logic low level when the reset signal RST is generated at a logic high level to begin the initialization operation. The flip-flop 241-2 receives and latches the signal from inverting output terminal QB as feedback through input terminal D and outputs the signal from inverting output terminal QB through the output terminal Q at the time when the first bit MCNT4<0> of the fourth mode control signal is generated at a logic high level. Thus, the flip-flop 241-2 inverts the logic level of output terminal Q at the time when the first bit MCNT4<0> of the fourth mode control signal is generated at a logic high level. The inverter 243-2 inversely buffers the output signal of the flip-flop 241-2 to output an inversely buffered signal from the output of the flip-flop 241-2. The selector 245-2 outputs the output signal of the flip-flop 241-2 or the output signal of the inverter 243-2 as the second bit MCNT4<1> of the fourth mode control signal according to the second bit SID<0> of the slice ID. To select the refresh mode of the fourth slice chip 110-4, the selector 245-2 outputs the output signal of the inverter 243-2 as the second bit MCNT4<1> of the fourth mode control signal according to the second bit SID<0> of the slice ID at a logic high level.

The operation of the fourth mode control signal generation circuit 134-1 is described with reference to FIG. 9 and FIG. 10. When the first bit SID<0> of the slice ID and the second bit SID<1> of the slice ID are at a logic high level to select the refresh mode of the fourth slice chip 110-4, operation of the fourth mode control signal generation circuit 134-1 is performed.

As shown in FIG. 9 and a first data row in FIG. 10, when the reset signal RST is generated at a logic high level to begin the initialization operation, the flip-flop 241-1 outputs the fourth pre-control signal PCNT4 at a logic low level L, the selector 245-1 outputs the first bit MCNT4<0> of the fourth mode control signal of a logic high level H according to the first bit SID<0> of the slice ID at a logic high level H, and the selector 245-2 outputs the second bit MCNT4<1> of the fourth mode control signal at a logic high level H according to the second bit SID<1> of the slice ID at a logic high level H.

As shown in FIG. 9 and a second data row in FIG. 10, after the initialization operation, when the refresh bank signal that refreshes banks included in the fourth slice chip 110-4 is generated and the clock signal MS-CLK toggles for a first time, the flip-flop 241-1 outputs the fourth pre-control signal PCNT4 at a logic high level H, the selector 245-1 outputs the first bit MCNT4<0> of the fourth mode control signal of a logic low level L according to the first bit SID<0> of the slice ID at a logic high level H, and the selector 245-2 outputs the second bit MCNT4<1> of the fourth mode control signal at a logic low level L according to the second bit SID<1> of the slice ID at a logic high level H.

As shown in FIG. 9 and a third data row in FIG. 10, the refresh bank signal that refreshes banks included in the fourth slice chip 110-4 is generated and the clock signal MS-CLK toggles for a second time, the flip-flop 241-1 outputs the fourth pre-control signal PCNT4 at a logic low level L, the selector 245-1 outputs the first bit MCNT4<0> of the fourth mode control signal of a logic high level H according to the first bit SID<0> of the slice ID at a logic high level H, and the selector 245-2 outputs the second bit MCNT4<1> of the fourth mode control signal at a logic low level L according to the second bit SID<1> of the slice ID at a logic high level H.

As shown in FIG. 9 and a fourth data row in FIG. 10, the refresh bank signal that refreshes banks included in the fourth slice chip 110-4 is generated and the clock signal MS-CLK toggles for a third time, the flip-flop 241-1 outputs the fourth pre-control signal PCNT4 at a logic high level H, the selector 245-1 outputs the first bit MCNT4<0> of the fourth mode control signal at a logic low level L according to the first bit SID<0> of the slice ID at a logic high level H, and the selector 245-2 outputs the second bit MCNT4<1> of the fourth mode control signal at a logic high level H according to the second bit SID<1> of the slice ID at a logic high level H.

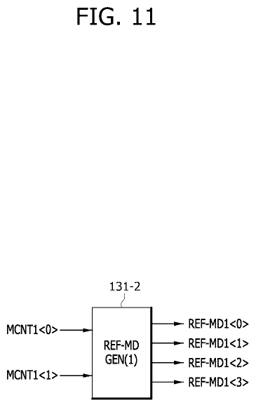

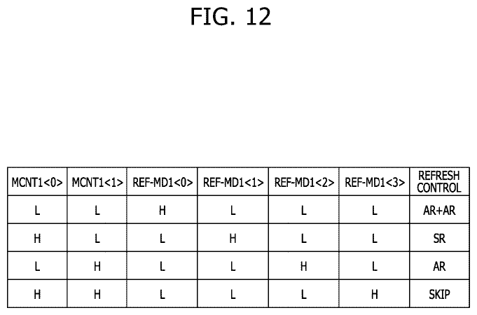

FIG. 11 is a circuit diagram illustrating a first refresh mode selecting signal generation circuit 131-2 according to an embodiment of the present disclosure, and FIG. 12 is a table including data during operation of the first refresh mode selecting signal generation circuit 131-2 according to an embodiment of the present disclosure.

As shown in FIG. 11 and FIG. 12, the first refresh mode selecting signal generation circuit 131-2 generates a first bit REF-MD1<0> of a first refresh mode selecting signal, a second bit REF-MD1<1> of the first refresh mode selecting signal, a third bit REF-MD1<2> of the first refresh mode selecting signal, and a fourth bit REF-MD1<3> of the first refresh mode selecting signal that selects the refresh mode of the first slice chip 110-1 based on the first bit MCNT1<0> of the first mode control signal and the second bit MCNT1<1> of the first mode control signal.

As shown in FIG. 11 and FIG. 12, the first refresh mode selecting signal generation circuit 131-2 generates the first bit REF-MD1<0> of the first refresh mode selecting signal at a logic high level H and generates the second bit REF-MD1<1> of the first refresh mode selecting signal, the third bit REF-MD1<2> of the first refresh mode selecting signal, and the fourth bit REF-MD1<3> of the first refresh mode selecting signal at a logic low level L according to the first bit set including the first bit MCNT1<0> of the first mode control signal and the second bit MCNT1<1> of the first mode control signal, where the first bit MCNT1<0> of the first mode control signal and the second bit MCNT1<1> of the first mode control signal are at a logic low level L. Because the refresh operation of the first slice chip 110-1 is the first refresh mode when the first bit REF-MD1<0> of the first refresh mode selecting signal is at a logic high level H, an auto-refresh operation is performed twice for banks included in the first slice chip 110-1.

As shown in FIG. 11 and FIG. 12, the first refresh mode selecting signal generation circuit 131-2 generates the second bit REF-MD1<1> of the first refresh mode selecting signal at a logic high level H and generates the first bit REF-MD1<0> of the first refresh mode selecting signal, the third bit REF-MD1<2> of the first refresh mode selecting signal, and the fourth bit REF-MD1<3> of the first refresh mode selecting signal at a logic low level L according to a second bit set including the first bit MCNT1<0> of the first mode control signal and the second bit MCNT1<1> of the first mode control signal, where the first bit MCNT1<0> of the first mode control signal is at a logic high level H and the second bit MCNT1<1> of the first mode control signal is at a logic low level L. Because the refresh operation of the first slice chip 110-1 is the second refresh mode when the second bit REF-MD1<1> of the first refresh mode selecting signal is at a logic high level H, a smart refresh operation is performed for banks included in the first slice chip 110-1.

As shown in FIG. 11 and FIG. 12, the first refresh mode selecting signal generation circuit 131-2 generates the third bit REF-MD1<2> of the first refresh mode selecting signal at a logic high level H and generates the first bit REF-MD1<0> of the first refresh mode selecting signal, the second bit REF-MD1<1> of the first refresh mode selecting signal, and the fourth bit REF-MD1<3> of the first refresh mode selecting signal at a logic low level L according to a third bit set including the first bit MCNT1<0> of the first mode control signal and the second bit MCNT1<1> of the first mode control signal, where the first bit MCNT1<0> of the first mode control signal at a logic low level L and the second bit MCNT1<1> of the first mode control signal at a logic high level H. Because the refresh operation of the first slice chip 110-1 is the third refresh mode when the third bit REF-MD1<2> of the first refresh mode selecting signal is at a logic high level H, an auto-refresh operation is performed for banks included in the first slice chip 110-1.

As shown in FIG. 11 and FIG. 12, the first refresh mode selecting signal generation circuit 131-2 generates the fourth bit REF-MD1<3> of the first refresh mode selecting signal at a logic high level H and generates the first bit REF-MD1<0> of the first refresh mode selecting signal, the second bit REF-MD1<1> of the first refresh mode selecting signal, and the third bit REF-MD1<2> of the first refresh mode selecting signal at a logic low level L according to a fourth bit set including the first bit MCNT1<0> of the first mode control signal and the second bit MCNT1<1> of the first mode control signal, where the first bit MCNT1<0> of the first mode control signal at a logic high level H and the second bit MCNT1<1> of the first mode control signal at a logic high level H. Because the refresh operation of the first slice chip 110-1 is the fourth refresh mode when the fourth bit REF-MD1<3> of the first refresh mode selecting signal is at a logic high level H, a refresh operation for all banks included in the first slice chip 110-1 is not performed or skipped.

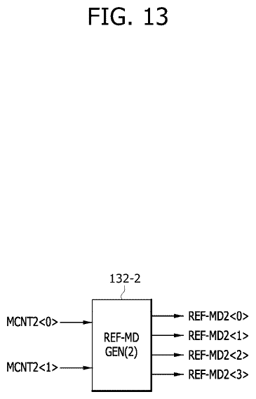

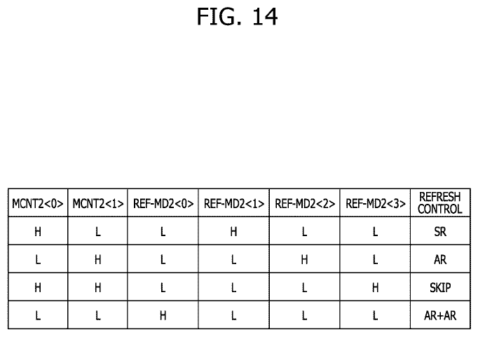

FIG. 13 is a circuit diagram illustrating a second refresh mode selecting signal generation circuit 132-2 according to an embodiment of the present disclosure, and FIG. 14 is a table including data during operation of the second refresh mode selecting signal generation circuit 132-2 according to an embodiment of the present disclosure.

As shown in FIG. 13 and FIG. 14, the second refresh mode selecting signal generation circuit 132-2 generates a first bit REF-MD2<0> of the second refresh mode selecting signal, a second bit REF-MD2<1> of the second refresh mode selecting signal, a third bit REF-MD2<2> of the second refresh mode selecting signal, and a fourth bit REF-MD2<3> of the second refresh mode selecting signal that selects the refresh mode of the second slice chip 110-2 based on a first bit MCNT2<0> of the second mode control signal and a second bit MCNT2<1> of the second mode control signal.

As shown in FIG. 13 and FIG. 14, the second refresh mode selecting signal generation circuit 132-2 generates the second bit REF-MD2<1> of the second refresh mode selecting signal at a logic high level H and generates the first bit REF-MD2<0> of the second refresh mode selecting signal, the third bit REF-MD2<2> of the second refresh mode selecting signal, and the fourth bit REF-MD2<3> of the second refresh mode selecting signal at a logic low level L according to the second bit set including the first bit MCNT2<0> of the second mode control signal and the second bit MCNT2<1> of the second mode control signal, where the first bit MCNT2<0> of the second mode control signal is at a logic high level H and the second bit MCNT2<1> of the second mode control signal is at a logic low level L. Because the refresh operation of the second slice chip 110-2 is the second refresh mode when the second bit REF-MD2<1> of the second refresh mode selecting signal is at a logic high level H, a smart refresh operation is performed for banks included in the second slice chip 110-2.

As shown in FIG. 13 and FIG. 14, the second refresh mode selecting signal generation circuit 132-2 generates the third bit REF-MD2<2> of the second refresh mode selecting signal at a logic high level H and generates the first bit REF-MD2<0> of the second refresh mode selecting signal, the second bit REF-MD2<1> of the second refresh mode selecting signal, and the fourth bit REF-MD2<3> of the second refresh mode selecting signal at a logic low level L according to a third bit set including the first bit MCNT2<0> of the second mode control signal and the second bit MCNT2<1> of the second mode control signal, where the first bit MCNT2<0> of the second mode control signal is at a logic low level L and the second bit MCNT2<1> of the second mode control signal is at a logic high level H. Because the refresh operation of the second slice chip 110-2 is the third refresh mode when the third bit REF-MD2<2> of the second refresh mode selecting signal is at a logic high level H, an auto-refresh operation is performed for banks included in the second slice chip 110-2.

As shown in FIG. 13 and FIG. 14, the second refresh mode selecting signal generation circuit 132-2 generates the fourth bit REF-MD2<3> of the second refresh mode selecting signal at a logic high level H and generates the first bit REF-MD2<0> of the second refresh mode selecting signal, the second bit REF-MD2<1> of the second refresh mode selecting signal, and the third bit REF-MD2<2> of the second refresh mode selecting signal at a logic low levels L according to a fourth bit set including the first bit MCNT2<0> of the second mode control signal and the second bit MCNT2<1> of the second mode control signal, where the first bit MCNT2<0> of the second mode control signal is at a logic high level H and the second bit MCNT2<1> of the second mode control signal is at a logic high level H. Because the refresh operation of the second slice chip 110-2 is the fourth refresh mode when the fourth bit REF-MD2<3> of the second refresh mode selecting signal is at a logic high level H, the refresh operation for banks included in the second slice chip 110-2 is not performed or skipped.

As shown in FIG. 13 and FIG. 14, the second refresh mode selecting signal generation circuit 132-2 generates the first bit REF-MD2<0> of the second refresh mode selecting signal at a logic high level H and generates the second bit REF-MD2<1> of the second refresh mode selecting signal, the third bit REF-MD2<2> of the second refresh mode selecting signal, and the fourth bit REF-MD2<3> of the second refresh mode selecting signal at a logic low level L according to a first bit set including the first bit MCNT2<0> of the second mode control signal and the second bit MCNT2<1> of the second mode control signal, where the first bit MCNT2<0> of the second mode control signal and the second bit MCNT2<1> of the second mode control signal are at a logic low level L. Because the refresh operation of the second slice chip 110-2 is the first refresh mode when the first bit REF-MD2<0> of the second refresh mode selecting signal is at a logic high level H, an auto-refresh operation is performed twice for banks included in the second slice chip 110-2.

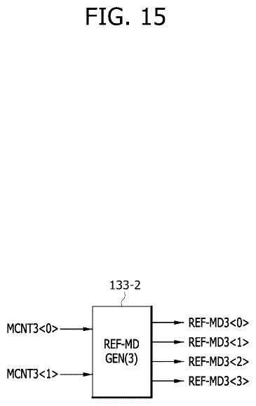

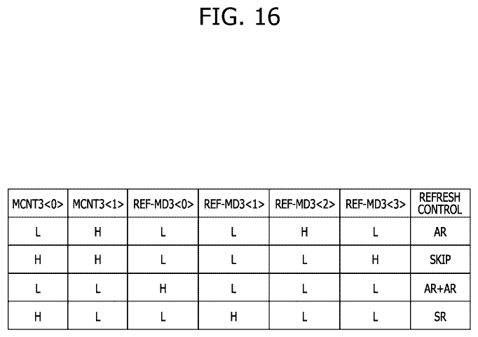

FIG. 15 is a circuit diagram illustrating a third refresh mode selecting signal generation circuit 133-2 according to an embodiment of the present disclosure, and FIG. 16 is a table including data during operation of the third refresh mode selecting signal generation circuit 133-2 according to an embodiment of the present disclosure.

As shown in FIG. 15 and FIG. 16, the third refresh mode selecting signal generation circuit 133-2 generates a first bit REF-MD3<0> of the third refresh mode selecting signal, a second bit REF-MD3<1> of the third refresh mode selecting signal, a third bit REF-MD3<2> of the third refresh mode selecting signal, and a fourth bit REF-MD3<3> of the third refresh mode selecting signal that selects the refresh mode of the third slice chip 110-3 based on the first bit MCNT3<0> of the third mode control signal and the second bit MCNT3<1> of the third mode control signal.

As shown in FIG. 15 and FIG. 16, the third refresh mode selecting signal generation circuit 133-2 generates the third bit REF-MD3<2> of the third refresh mode selecting signal at a logic high level H and generates the first bit REF-MD3<0> of the third refresh mode selecting signal, the second bit REF-MD3<1> of the third refresh mode selecting signal, and the fourth bit REF-MD3<3> of the third refresh mode selecting signal at a logic low level L according to a third bit set including the first bit MCNT3<0> of the third mode control signal and the second bit MCNT3<1> of the third mode control signal, where the first bit MCNT3<0> of the third mode control signal is at a logic low level L and the second bit MCNT3<1> of the third mode control signal is at a logic high level H. Because the refresh operation of the third slice chip 110-3 is the third refresh mode when the third bit REF-MD3<2> of the third refresh mode selecting signal is at a logic high level H, an auto-refresh operation is performed for banks included in the third slice chip 110-3.

As shown in FIG. 15 and FIG. 16, the third refresh mode selecting signal generation circuit 133-2 generates the fourth bit REF-MD3<3> of the third refresh mode selecting signal at a logic high level H and generates the first bit REF-MD3<0> of the third refresh mode selecting signal, the second bit REF-MD3<1> of the third refresh mode selecting signal, and the third bit REF-MD3<2> of the third refresh mode selecting signal at a logic low level L according to a fourth bit set including the first bit MCNT3<0> of the third mode control signal and the second bit MCNT3<1> of the third mode control signal, where the first bit MCNT3<0> of the third mode control signal is at a logic high level H and the second bit MCNT3<1> of the third mode control signal is at a logic high level H. Because the refresh operation of the third slice chip 110-3 is the fourth refresh mode when the fourth bit REF-MD3<3> of the third refresh mode selecting signal is at a logic high level H, the refresh operation for banks included in the third slice chip 110-3 is not performed or skipped.

As shown in FIG. 15 and FIG. 16, the third refresh mode selecting signal generation circuit 133-2 generates the first bit REF-MD3<0> of the third refresh mode selecting signal at a logic high level H and generates the second bit REF-MD3<1> of the third refresh mode selecting signal, the third bit REF-MD3<2> of the third refresh mode selecting signal, and the fourth bit REF-MD3<3> of the third refresh mode selecting signal at a logic low level L according to a first bit set including the first bit MCNT3<0> of the third mode control signal and the second bit MCNT3<1> of the third mode control signal, where the first bit MCNT3<0> of the third mode control signal and the second bit MCNT3<1> of the third mode control signal are at a logic low level L. Because the refresh operation of the third slice chip 110-3 is the first refresh mode when the first bit REF-MD3<0> of the third refresh mode selecting signal is at a logic high level H, an auto-refresh operation is performed twice for banks included in the third slice chip 110-3.

As shown in FIG. 15 and FIG. 16, the third refresh mode selecting signal generation circuit 133-2 generates the second bit REF-MD3<1> of the third refresh mode selecting signal at a logic high level H and generates the first bit REF-MD3<0> of the third refresh mode selecting signal, the third bit REF-MD3<2> of the third refresh mode selecting signal, and the fourth bit REF-MD3<3> of the third refresh mode selecting signal at a logic low level L according to a second bit set including the first bit MCNT3<0> of the third mode control signal and the second bit MCNT3<1> of the third mode control signal, where the first bit MCNT3<0> of the third mode control signal is at a logic high level H and the second bit MCNT3<1> of the third mode control signal is at a logic low level L. Because the refresh operation of the third slice chip 110-3 is the second refresh mode according to the second bit REF-MD3<1> of the third refresh mode selecting signal at a logic high level H, a smart refresh operation is performed for banks included in the third slice chip 110-3.

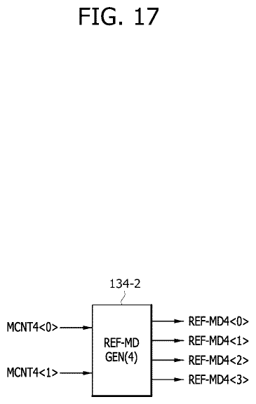

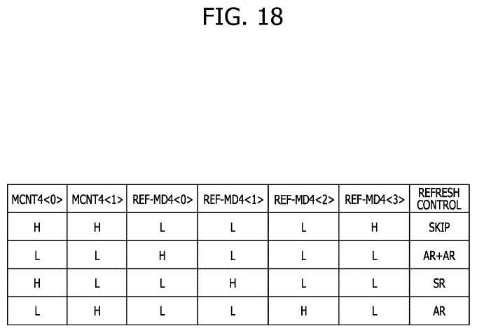

FIG. 17 is a circuit diagram illustrating a fourth refresh mode selecting signal generation circuit 134-2 according to an embodiment of the present disclosure, and FIG. 18 is a table including data during operation of the fourth refresh mode selecting signal generation circuit 134-2 according to an embodiment of the present disclosure.

As shown in FIG. 17 and FIG. 18, the fourth refresh mode selecting signal generation circuit 134-2 generates a first bit REF-MD4<0> of the fourth refresh mode selecting signal, a second bit REF-MD4<1> of the fourth refresh mode selecting signal, a third bit REF-MD4<2> of the fourth refresh mode selecting signal, and a fourth bit REF-MD4<3> of the fourth refresh mode selecting signal that selects the refresh mode of the fourth slice chip 110-4 based on a first bit MCNT4<0> of the fourth mode control signal and a second bit MCNT4<1> of the fourth mode control signal.

As shown in FIG. 17 and FIG. 18, the fourth refresh mode selecting signal generation circuit 134-2 generates the fourth bit REF-MD4<3> of the fourth refresh mode selecting signal at a logic high level H and generates the first bit REF-MD4<0> of the fourth refresh mode selecting signal, the second bit REF-MD4<1> of the fourth refresh mode selecting signal, and the third bit REF-MD4<2> of the fourth refresh mode selecting signal at a logic low level L according to a fourth bit set including the first bit MCNT4<0> of the fourth mode control signal and the second bit MCNT4<1> of the fourth mode control signal, where the first bit MCNT4<0> of the fourth mode control signal is at a logic high level H and the second bit MCNT4<1> of the fourth mode control signal is at a logic high level H. Because the refresh operation of the fourth slice chip 110-4 is the fourth refresh mode when the fourth bit REF-MD4<3> of the fourth refresh mode selecting signal is at a logic high level H, the refresh operation for banks included in the fourth slice chip 110-4 is not performed or skipped.

As shown in FIG. 17 and FIG. 18, the fourth refresh mode selecting signal generation circuit 134-2 generates the first bit REF-MD4<0> of the fourth refresh mode selecting signal at a logic high level H and generates the second bit REF-MD4<1> of the fourth refresh mode selecting signal, the third bit REF-MD4<2> of the fourth refresh mode selecting signal, and the fourth bit REF-MD4<3> of the fourth refresh mode selecting signal at a logic low level L according to a first bit set including the first bit MCNT4<0> of the fourth mode control signal and the second bit MCNT4<1> of the fourth mode control signal, where the first bit MCNT4<0> of the fourth mode control signal and the second bit MCNT4<1> of the fourth mode control signal are at a logic low level L. Because the refresh operation of the fourth slice chip 110-4 is the first refresh mode when the fourth bit REF-MD4<0> of the fourth refresh mode selecting signal is at a logic high level H, an auto-refresh operation is performed twice for banks included in the fourth slice chip 110-4.

As shown in FIG. 17 and FIG. 18, the fourth refresh mode selecting signal generation circuit 134-2 generates the second bit REF-MD4<1> of the fourth refresh mode selecting signal at a logic high level H and generates the first bit REF-MD4<0> of the fourth refresh mode selecting signal, the third bit REF-MD4<2> of the fourth refresh mode selecting signal, and the fourth bit REF-MD4<3> of the fourth refresh mode selecting signal at a logic low level L according to a second bit set including the first bit MCNT4<0> of the fourth mode control signal and the second bit MCNT4<1> of the fourth mode control signal, where the first bit MCNT4<0> of the fourth mode control signal is at a logic high level H and the second bit MCNT4<1> of the fourth mode control signal is at a logic low level L. Because the refresh operation of the fourth slice chip 110-4 is the second refresh mode when the second bit REF-MD4<1> of the fourth refresh mode selecting signal is at a logic high level H, a smart refresh operation is performed for banks included in the fourth slice chip 110-4.

As shown in FIG. 17 and FIG. 18, the fourth refresh mode selecting signal generation circuit 134-2 generates the third bit REF-MD4<2> of the fourth refresh mode selecting signal at a logic high level H and generates the first bit REF-MD4<0> of the fourth refresh mode selecting signal, the second bit REF-MD4<1> of the fourth refresh mode selecting signal, and the fourth bit REF-MD4<3> of the fourth refresh mode selecting signal at a logic low level L according to a third bit set including the first bit MCNT4<0> of the fourth mode control signal and the second bit MCNT4<1> of the fourth mode control signal, where the first bit MCNT4<0> of the fourth mode control signal is at a logic low level L and the second bit MCNT4<1> of the fourth mode control signal is at a logic high level H. Because the refresh operation of the fourth slice chip 110-4 is the third refresh mode when the third bit REF-MD4<2> of the fourth refresh mode selecting signal is at a logic high level H, an auto-refresh operation is performed for banks included in the fourth slice chip 110-4.

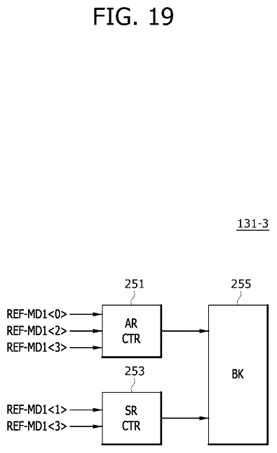

FIG. 19 is a circuit diagram illustrating a first refresh control circuit 131-3 according to an embodiment of the present disclosure. As shown in FIG. 19, the first refresh control circuit 131-3 includes an auto-refresh control circuit (AR CTR) 251, a smart refresh control circuit (SR CTR) 253, and a bank (BK) 255.

The auto-refresh control circuit 251 controls whether to perform the auto-refresh operation for the bank 255 included in the first slice chip 110-1 based on the first bit REF-MD1<0> of the first refresh mode selecting signal, the third bit REF-MD1<2> of the first refresh mode selecting signal, and the fourth bit REF-MD1<3> of the first refresh mode selecting signal. For example, when the auto-refresh control circuit 251 receives the first bit REF-MD1<0> of the first refresh mode selecting signal at a logic high level, the third bit REF-MD1<2> of the first refresh mode selecting signal at a logic low level, and the fourth bit REF-MD1<3> of the first refresh mode selecting signal at a logic low level, the refresh mode of the refresh operation performed on the bank 255 included in the first slice chip 110-1 is the first refresh mode, the auto-refresh operation on the bank 255 is performed twice. For example, when the auto refresh control circuit 251 receives the third bit REF-MD1<2> of the first refresh mode selecting signal at a logic high level, the first bit REF-MD1<0> of the first refresh mode selecting signal at a logic low level, and the fourth bit REF-MD1<3> of the first refresh mode selecting signal at a logic low level, the refresh mode of the refresh operation performed on the bank 255 included in the first slice chip 110-1 is the third refresh mode, the auto-refresh operation on the bank 255 is performed. For example, when the auto refresh control circuit 251 receives the fourth bit REF-MD1<3> of the first refresh mode selecting signal at a logic high level, the first bit REF-MD1<0> of the first refresh mode selecting signal at a logic low level, and the third bit REF-MD1<2> of the first refresh mode selecting signal at a logic low level, the refresh mode of the refresh operation performed on the bank 255 included in the first slice chip 110-1 is the fourth refresh mode, the auto-refresh operation on the bank 255 is not performed.

The smart refresh control circuit 253 controls whether to perform the smart refresh operation for the bank 255 included in the first slice chip 110-1 based on the second bit REF-MD1<1> of the first refresh mode selecting signal and the fourth bit REF-MD1<3> of the first refresh mode selecting signal. For example, when the smart refresh control circuit 253 receives the second bit REF-MD1<1> of the first refresh mode selecting signal at a logic high level and the fourth bit REF-MD1<3> of the first refresh mode selecting signal at a logic low level, the refresh mode of the refresh operation performed on the bank 255 included in the first slice chip 110-1 is the second refresh mode, and the smart refresh operation is performed for the bank 255. For example, when the smart refresh control circuit 253 receives the fourth bit REF-MD1<3> of the first refresh mode selecting signal at a logic high level and the second bit REF-MD1<1> of the first refresh mode selecting signal at a logic low level, the refresh mode of the refresh operation performed on the bank 255 included in the first slice chip 110-1 is the fourth refresh mode, the smart refresh operation on the bank 255 is not performed.

The first refresh control circuit 131-3 controls the first slice chip 110-1 such that the refresh operation is performed in the refresh mode based on the refresh bank signal REF-BK and the first refresh mode selecting signal REF-MD1. The second refresh control circuit 132-3 may be configured similar to the first refresh control circuit 131-3 in FIG. 19 to control the second slice chip 110-2 such that the refresh operation is performed in the refresh mode based on the refresh bank signal REF-BK and the second refresh mode selecting signal REF-MD2. The third refresh control circuit 133-3 may be configured similar to the first refresh control circuit 131-3 in FIG. 19 to control the third slice chip 110-3 such that the refresh operation is performed in the refresh mode based on the refresh bank signal REF-BK and the third refresh mode selecting signal REF-MD3. The fourth refresh control circuit 134-3 may be configured similar to the first refresh control circuit 131-3 in FIG. 19 to control the fourth slice chip 110-4 such that the refresh operation is performed in the refresh mode based on the refresh bank signal REF-BK and the fourth refresh mode selecting signal REF-MD4.

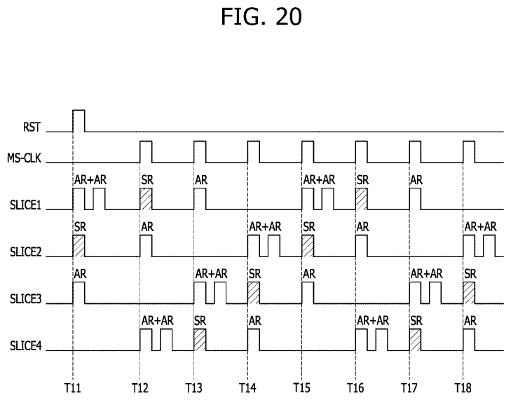

FIG. 20 is a timing diagram during the refresh mode performed for each slice chip.

During the time period from time T11 to time T12, a reset signal RST is generated at a logic high level to begin an initialization operation, and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the first refresh mode, the refresh operation on the second slice chip 110-2 is performed in the second refresh mode, the refresh operation on the third slice chip 110-3 is performed in the third refresh mode, and the refresh operation on the fourth slice chip 110-4 is performed in the fourth refresh mode. During the period from time T11 to time T12, the auto-refresh operation is performed twice for banks included in the first slice chip 110-1, the smart refresh operation is performed for banks included in the second slice chip 110-2, the auto-refresh operation is performed for banks included in the third slice chip 110-3, and the refresh operation is not performed or skipped for banks included in the fourth slice chip 110-4.

During the time period from time T12 to time T13, a first pulse of the clock signal MS-CLK is generated at a logic high level (the clock signal toggles), and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the second refresh mode, the refresh operation on the second slice chip 110-2 is performed in the third refresh mode, the refresh operation on the third slice chip 110-3 is performed in the fourth refresh mode, and the refresh operation on the fourth slice chip 110-4 is performed in the first refresh mode. During the period from time T12 to time T13, the smart refresh operation is performed for banks included in the first slice chip 110-1, the auto-refresh operation is performed for banks included in the second slice chip 110-2, the refresh operation is not performed or skipped for banks included in the third slice chip 110-3, and the auto-refresh operation is performed twice for banks included in the fourth slice chip 110-4.

During the time period from time T13 to time T14, a second pulse of the clock signal MS-CLK is generated at a logic high level, and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the third refresh mode, the refresh operation on the second slice chip 110-2 is performed in the fourth refresh mode, the refresh operation on the third slice chip 110-3 is performed in the first refresh mode, and the refresh operation on the fourth slice chip 110-4 is performed in the second refresh mode. During the period from time T13 to time T14, the auto-refresh operation is performed for all banks included in the first slice chip 110-1, the refresh operation is not performed or skipped for banks included in the second slice chip 110-2, the auto-refresh operation is performed twice for banks included in the third slice chip 110-3, and the smart refresh operation is performed for banks included in the fourth slice chip 110-4.

During the time period from time T14 to time T15, a third pulse of the clock signal MS-CLK is generated at a logic high level, and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the fourth refresh mode, the refresh operation on the second slice chip 110-2 is performed in the first refresh mode, the refresh operation on the third slice chip 110-3 is performed in the second refresh mode, and the refresh operation on the fourth slice chip 110-4 is performed in the third refresh mode. During the period from time T14 to time T15, the refresh operation for banks included in the first slice chip 110-1 is not performed or skipped, the auto-refresh operation for banks included in the second slice chip 110-2 is performed twice, the smart refresh operation for banks included in the third slice chip 110-3 is performed, and the auto-refresh operation for banks included in the fourth slice chip 110-4 is performed.

During the time period from time T15 to time T16, a fourth pulse of the clock signal MS-CLK is generated at a logic high level, and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the first refresh mode, the refresh operation on the second slice chip 110-2 is performed in the second refresh mode, the refresh operation on the third slice chip 110-3 is performed in the third refresh mode, and the refresh operation on the fourth slice chip 110-4 is performed in the fourth refresh mode. During the period from time T15 to time T16, the auto-refresh operation for banks included in the first slice chip 110-1 is performed twice, the smart refresh operation for banks included in the second slice chip 110-2 is performed, the auto-refresh operation for banks included in the third slice chip 110-3 is performed, and the refresh operation for banks included in the fourth slice chip 110-4 is not performed or skipped.

During the time period from time T16 to time T17, a fifth pulse of the clock signal MS-CLK is generated at a logic high level, and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the second refresh mode, the refresh operation on the second slice chip 110-2 is performed in the third refresh mode, the refresh operation on the third slice chip 110-3 is performed in the fourth refresh mode, and the refresh operation on the fourth slice chip 110-4 is performed in the first refresh mode. During the period from time T16 to time T17, the smart refresh operation for banks included in the first slice chip 110-1 is performed, the auto-refresh operation for banks included in the second slice chip 110-2 is performed, the refresh operation for all banks included in the third slice chip 110-3 is not performed or skipped, and the auto-refresh operation for all banks included in the fourth slice chip 110-4 is performed twice.

During the time period from time T17 to time T18, a sixth pulse of the clock signal MS-CLK is generated at a logic high level, and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the third refresh mode, the refresh operation on the second slice chip 110-2 is performed in the fourth refresh mode, the refresh operation on the third slice chip 110-3 is performed in the first refresh mode, and the refresh operation on the fourth slice chip 110-4 is performed in the second refresh mode. During the period from time T17 to time T18, the auto-refresh operation for banks included in the first slice chip 110-1 is performed, the refresh operation for banks included in the second slice chip 110-2 is not performed or skipped, the auto-refresh operation for banks included in the third slice chip 110-3 is performed twice, and the smart refresh operation for banks included in the fourth slice chip 110-4 is performed.

During the time period after time T18, a seventh pulse of the clock signal MS-CLK is generated at a logic high level, and the refresh bank signal is generated that refreshes banks included in the first slice chip 110-1, the second slice chip 110-2, the third slice chip 110-3, and the fourth slice chip 110-4. The refresh operation on the first slice chip 110-1 is performed in the fourth refresh mode, the refresh operation on the second slice chip 110-2 is performed in the first refresh mode, the refresh operation on the third slice chip 110-3 is performed in the second refresh mode, and the refresh operation on the fourth slice chip 110-4 is performed in the third refresh mode. During the period after time T18, the refresh operation for banks included in the first slice chip 110-1 is not performed or skipped, the auto-refresh operation for banks included in the second slice chip 110-2 is performed twice, the smart refresh operation for banks included in the third slice chip 110-3 is performed, and the auto-refresh operation for banks included in the fourth slice chip 110-4 is performed.

The refresh mode of the refresh operation performed in the first slice chip 110-1, the second slice chip 110-2, the third slice chip 110-3, and the fourth slice chip 110-4 of the stacked memory device 10 includes the first refresh mode in which the auto-refresh operation is performed twice, the second refresh mode in which the smart refresh operation is performed, the third refresh mode in which the auto-refresh operation is performed, and the fourth refresh mode in which the refresh operation is not performed or skipped. The current consumed during the refresh operation is reduced for each subsequent refresh operation when refresh operations are performed according to the order of the first refresh mode, the third refresh mode, the second refresh mode, and the fourth refresh mode. The first refresh mode has the largest current consumption, the second refresh mode has the second largest current consumption, the third refresh mode has the third largest current consumption, and the fourth refresh most has the smallest current consumption among the refresh modes. The stacked memory device 10 distributes the refresh mode with high current consumption to the first slice chip 110-1, the second slice chip 110-2, the third slice chip 110-3, and the fourth slice chip 110-4 using the slice ID SID, thereby reducing the amount of current consumption when the refresh operation is performed in the stacked memory device 10.

FIG. 21 is a block diagram illustrating a stacked memory system 3 according to an embodiment of the present disclosure. As shown in FIG. 21, the stacked memory system 3 includes a first stacked memory device 3100, a second stacked memory device 3200, a processor 3300, an interposer 3400, and a substrate 3500.

The interposer 3400 is disposed over the substrate 3500. The first stacked memory device 3100, the second stacked memory device 3200, and the processor 3300 are disposed over the interposer 3400. The processor 3300 is disposed between the first stacked memory device 3100 and the second stacked memory device 3200. The interposer 3400 electrically connects the substrate 3500, the first stacked memory device 3100, the second stacked memory device 3200, and the processor 3300. When the pitch differences between the first stacked memory device 3100, the second stacked memory device 3200, and the processor 3300 are large, the first stacked memory device 3100, the second stacked memory device 3200, and the processor 3300 are electrically connected using the interposer 3400 including variously formed wires.

The processor 3300 includes a first controller 3310 that controls the first stacked memory device 3100 and a first process interface circuit 3320 electrically connecting the first stacked memory device 3100 to the first controller 3310. The processor 3300 includes a second controller 3330 that controls the second stacked memory device 3200 and a second process interface circuit 3340 electrically connecting the second stacked memory device 3100 to the second controller 3330. The processor 3300 conveys signals including commands and addresses that control various internal operations of the first stacked memory device 3100 to the first stacked memory device 3100 through the first process interface circuit 3320 and receives signals from the first stacked memory device 3100 through the first process interface circuit 3320. The processor 3300 conveys signals including commands and addresses that control various internal operations of the second stacked memory device 3200 to the second stacked memory device 3200 through the second process interface circuit 3340 and receives signals from the second stacked memory device 3200 through the second process interface circuit 3340.

The first stacked memory device 3100 includes a first base chip 3110 and first core chips 3120, 3130, 3140, and 3150. The first core chips 3120, 3130, 3140, and 3150 are sequentially stacked over the first base chip 3110 and receive various signals from the first base chip 3110 through TSVs. In FIG. 21, the first stacked memory device 3100 includes four first core chips 3120, 3130, 3140, and 3150, but may be formed including four first core chips, eight first core chips, sixteen first core chips, or other quantities of first core chips. The first stacked memory device 3100 is implemented, for example, with the stacked memory device 10 shown in FIG. 1.

The first base chip 3110 includes a first core interface circuit 3111. The first core interface circuit 3111 is configured to communicate with the first processor interface circuit 3320 to receive signals transmitted from the processor 3300 and conveys signals generated from the first core chips 3120, 3130, 3140, and 3150 to the processor 3300.

The second stacked memory device 3200 includes a second base chip 3210 and second core chips 3220, 3230, 3240, and 3250. The second core chips 3220, 3230, 3240, and 3250 are sequentially stacked over the second base chip 3210 and receive various signals from the second base chip 3210 through TSVs. In FIG. 21, the second stacked memory device 3200 includes four second core chips 3220, 3230, 3240, and 3250, but may be formed including four second core chips, eight second core chips, sixteen second core chips, or other quantities of second core chips. The second stacked memory device 3200 is implemented, for example, with the stacked memory device 10 illustrated in FIG. 1.

The second base chip 3210 includes a second core interface circuit 3211. The second core interface circuit 3211 is configured to communicate with the second processor interface circuit 3330 to receive signals transmitted from the processor 3300 and conveys signals generated from the second core chips 3220, 3230, 3240, and 3250 to the processor 3300.

FIG. 22 is a block diagram illustrating a stacked memory system 4 according to an embodiment of the present disclosure. As shown in FIG. 22, the stacked memory system 4 includes a first stacked memory device 4100, a second stacked memory device 4200, a system control device 4300, a substrate 4400, and a main board 4500.

The substrate 4400 is disposed over the main board 4500, the system control device 4300 is disposed over the substrate 4400, and the first stacked memory device 4100 and the second stacked memory device 4200 are disposed over the system control device 4300. The system control device 4300 includes a processor 4310, a first controller 4320, a first process interface circuit 4330, a second controller 4340, and a second process interface circuit 4350.

The processor 4310 is electrically connected to the first controller 4320 to control various internal operations of the first stacked memory device 4100. The processor 4310 conveys, to the first stacked memory device 4100 through the first process interface circuit 4330, signals including commands and addresses that control various internal operations of the first stacked memory device 4100 and receives signals from the first stacked memory device 4100 through the first process interface circuit 4330. The processor 4310 is electrically connected to the second controller 4340 to control various internal operations of the second stacked memory device 4200. The processor 4310 conveys signals including commands and addresses that control various internal operations of the second stacked memory device 4100 to the second stacked memory device 4200 through the second process interface circuit 4350 and receives signals from the second stacked memory device 4200 through the second process interface circuit 4350.

The first stacked memory device 4100 includes a first base chip 4110 and first core chips 4120, 4130, 4140, and 4150. The first stacked memory device 4100 is implemented, for example, with the semiconductor device 10 as shown in FIG. 1. The first core chips 4120, 4130, 4140, and 4150 are sequentially stacked over the first base chip 4110 and receive various signals from the first base chip 4110 through TSVs. In FIG. 22, the first stacked memory device 4100 includes four first core chips 4120, 4130, 4140, and 4150, but may be formed including four first core chips, eight first core chips, twelve first core chips, sixteen first core chips, or other quantities of first core chips. The first stacked memory device 4100 is implemented, for example, with the stacked memory device 10 shown in FIG. 1.

The first base chip 4110 includes a first core interface circuit 4111. The first core interface circuit 4111 is configured to communicate with the first processor interface circuit 4330 to receive signals transmitted from the processor 4310 and convey signals generated from the first core chips 4120, 4130, 4140, and 4150 to the processor 4310.

The second stacked memory device 4200 includes second core chips 4210, 4220, 4230, and 4240. The second core chips 4210, 4220, 4230, and 4240 are sequentially stacked and receive various signals through TSVs. In FIG. 22, the second stacked memory device 4200 includes four second core chips 4210, 4220, 4230, and 4240, but may be formed including four second core chips, eight second core chips, sixteen second core chips, or other quantities of second core chips. The second stacked memory device 4200 is formed by stacking core chips without a base chip. The second stacked memory device 4200 is implemented, for example, with the stacked memory device 10 shown in FIG. 1.

The second stacked memory device 4200 is configured to communicate with the second processor interface circuit 4350 to receive signals transmitted from the processor 4310 and convey signals generated from the second core chips 4210, 4220, 4230, and 4240 to the processor 4310.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not considered a restrictive standpoint. The scope of the present disclosure is not limited to the descriptions, and all distinctive features within an equivalent scope should be construed as included in the present disclosure. All changes within the meaning and range of equivalency of the claims are included within their scope.

What is claimed is:

1. A stacked memory device comprising:
a base chip;
a first slice chip stacked over the base chip; and
a second slice chip stacked over the first slice chip;
wherein the base chip comprises a slice control circuit configured to control the first slice chip and the second slice chip such that a refresh operation is performed according to a refresh mode of the first slice chip and a refresh mode of the second slice chip when a refresh bank signal is generated that refreshes banks included in the first slice chip and the second slice chip.

2. The stacked memory device of claim 1, wherein the slice control circuit is configured to control the first slice chip such that refresh operations are performed sequentially and repeatedly according to an order of a first refresh mode, a second refresh mode, a third refresh mode, and a fourth refresh mode for refreshing banks included in the first slice chip.

3. The stacked memory device of claim 2, wherein the slice control circuit is configured to control the first slice chip such that during the first refresh mode an auto-refresh operation is performed twice for banks included in the first slice chip, during the second refresh mode a smart refresh operation is performed, during the third refresh mode the auto-refresh operation is performed, and during the fourth refresh mode a refresh operation is not performed.

4. The stacked memory device of claim 2, wherein the slice control circuit is configured to control the second slice chip such that refresh operations are performed sequentially and repeatedly according to an order of the second refresh mode, the third refresh mode, the fourth refresh mode, and the first refresh mode for refreshing banks included in the second slice chip.

5. The stacked memory device of claim 4, wherein the slice control circuit is configured to control the second slice chip such that during the second refresh mode the smart refresh operation is performed for banks included in the second slice chip, during the third refresh mode the auto-refresh operation is performed, during the fourth refresh mode a refresh operation is not performed, and during the first refresh mode the auto-refresh operation is performed twice.

6. The stacked memory device of claim 1, wherein the slice control circuit comprises:
a control circuit configured to generate a clock signal that toggles when the refresh bank signal is generated that refreshes banks included in the first slice chip and the second slice chip; and
a first slice refresh control circuit configured to select the refresh mode of the first slice chip based on the clock signal, a reset signal, and a slice identification (ID).

7. The stacked memory device of claim 6, wherein the control circuit comprises:
a command address decoder configured to decode a command address to generate a refresh command;
a refresh bank signal generation circuit configured to generate, based on the refresh command, the refresh bank signal that selects at least one bank on which the refresh operation is performed among the banks included in the first slice chip and the second slice chip; and
a clock signal generation circuit configured to generate the clock signal when the refresh bank signal is generated for banks included in the first slice chip and the second slice chip.

8. The stacked memory device of claim 7,
wherein the command address decoder generates the refresh command; and
wherein the refresh command comprises an all-bank refresh command generated to simultaneously perform the refresh operation on all banks included in the first slice chip and the second slice chip, and a per-bank refresh command generated to independently perform the refresh operation on each of the banks included in the first slice chip and the second slice chip.

9. The stacked memory device of claim 6, wherein the first slice refresh control circuit is configured to:
control the refresh operation performed on the first slice chip during the first refresh mode according to the slice ID when the reset signal is generated at a predetermined logic level to begin an initialization operation; and
control the refresh operation performed on the first slice chip during the second refresh mode according to the slice ID when the clock signal is toggled a first time after the initialization operation.

10. The stacked memory device of claim 9, wherein the first slice refresh control circuit is configured to:
control the refresh operation performed on the first slice chip during the third refresh mode according to the slice ID when the clock signal is toggled a second time;
control the refresh operation performed on the first slice chip during the fourth refresh mode according to the slice ID when the clock signal is toggled a third time; and
control the refresh operation performed on the first slice chip during the first refresh mode according to the slice ID when the clock signal is toggled a fourth time.

11. The stacked memory device of claim 6, wherein the first slice refresh control circuit comprises:
a first mode control signal generation circuit configured to generate a first mode control signal based on the clock signal, the reset signal, and the slice ID;
a first refresh mode selecting signal generation circuit configured to generate a first refresh mode selecting signal according to a bit set of the first mode control signal; and
a first refresh control circuit configured to control the refresh operation on the first slice chip and select the refresh mode of the first slice chip based on the refresh bank signal and the first refresh mode selecting signal.

12. The stacked memory device of claim 6, wherein the slice control circuit further comprises a second slice refresh control circuit configured to select the refresh mode of the second slice chip based on the clock signal, the reset signal, and the slice ID.

13. The stacked memory device of claim 12, wherein the second slice refresh control circuit is configured to:
control the refresh operation performed on the second slice chip during the second refresh mode according to the slice ID when the reset signal is generated at a predetermined logic level to begin an; and
control the refresh operation performed on the second slice chip during the third refresh mode according to the slice ID when the clock signal is toggled a first time after the initialization operation.

14. The stacked memory device of claim 13, wherein the second slice refresh control circuit is configured to:
control the refresh operation performed on the second slice chip during the fourth refresh mode according to the slice ID when the clock signal is toggled a second time;
control the refresh operation performed on the second slice chip during the first refresh mode according to the slice ID when the clock signal is toggled a third time; and
control the refresh operation performed on the second slice chip during the second refresh mode according to the slice ID when the clock signal is toggled a fourth time.

15. The stacked memory device of claim 12, wherein the second slice refresh control circuit comprises:
a second mode control signal generation circuit configured to generate a second mode control signal based on the mode selecting signal, the reset signal, and the slice ID;
a second refresh mode selecting signal generation circuit configured to generate a second refresh mode selecting signal according to a bit set of the second mode control signal; and
a second refresh control circuit configured to control the refresh operation on the second slice chip and selects the refresh mode of the second slice chip based on the refresh bank signal and the second refresh mode selecting signal.

16. The stacked memory device of claim 1, further comprising a third slice chip stacked over the second slice chip, wherein the slice control circuit is configured to control the third slice chip such that the refresh operation is performed according to the refresh mode of the third slice chip when the refresh bank signal is generated that refreshes banks included in the third slice chip.

17. The stacked memory device of claim 16, wherein the slice control circuit is configured to control the third slice chip such that the refresh operations are performed sequentially and repeatedly according to an order of a third refresh mode, a fourth refresh mode, a first refresh mode, and a second refresh mode for refreshing banks included in the third slice chip.

18. The stacked memory device of claim 17, wherein the slice control circuit is configured to control the third slice chip such that during the third refresh mode an auto-refresh operation is performed for banks included in the third slice chip, during the fourth refresh mode the refresh operation is not performed, the first refresh mode performs the auto-refresh operation twice, and during the second refresh mode a smart refresh operation is performed.

19. A stacked memory device comprising:
a base chip;
a first slice chip stacked over the base chip; and
a second slice chip stacked over the first slice chip,
wherein the base chip comprises:
a control circuit configured to generate a clock signal that toggles when a refresh bank signal is generated that refreshes banks included in the first slice chip and the second slice chip; and
a first slice refresh control circuit configured to select a refresh mode of the first slice chip based on the clock signal, a reset signal, and a slice identification (ID).

20. The stacked memory device of claim 19, wherein the control circuit comprises:
a command decoder configured to decode a command address to generate a refresh command;
a refresh bank signal generation circuit configured to generate, based on the refresh command, the refresh bank signal that selects at least one bank on which the refresh operation is performed among the banks included in the first slice chip and the second slice chip; and
a clock signal generation circuit configured to generate the clock signal when the refresh bank signal is generated for banks included in the first slice chip and the second slice chip.

21. The stacked memory device of claim 20,
wherein the command address decoder is configured to generate the refresh command; and
wherein the refresh command comprises an all-bank refresh command generated to simultaneously perform the refresh operation for all banks included in each of the first slice chip and the second slice chip, and a per-bank refresh command generated to independently perform the refresh operation on each of the banks included in the first slice chip and the second slice chip.

22. The stacked memory device of claim 19, wherein the first slice refresh control circuit is configured to:
control the refresh operation performed on the first slice chip during a first refresh mode according to the slice ID when the reset signal is generated at a predetermined logic level to begin an initialization operation, and
control the refresh operation performed on the first slice chip during a second refresh mode according to the slice ID when the clock signal is toggled a first time after the initialization operation.

23. The stacked memory device of claim 22, wherein the first slice refresh control circuit is configured to:
control the refresh operation performed on the first slice chip during a third refresh mode according to the slice ID when the clock signal is toggled a second time;
control the refresh operation performed on the first slice chip during a fourth refresh mode according to the slice ID when the clock signal is toggled a third time; and
control the refresh operation performed on the first slice chip during the first refresh mode according to the slice ID when the clock signal is toggled a fourth time.

24. The stacked memory device of claim 19, wherein the first slice refresh control circuit comprises:
a first mode control signal generation circuit configured to generate a first mode control signal based on the clock signal, the reset signal, and the slice ID;
a first refresh mode selecting signal generation circuit configured to generate a first refresh mode selecting signal according to a bit set of the first mode control signal; and
a first refresh control circuit configured to control the refresh operation of the first slice chip and selects the refresh mode of the first slice chip based on the refresh bank signal and the first refresh mode selecting signal.

25. The stacked memory device of claim 19, wherein the slice control circuit further comprises a second slice refresh control circuit configured to select the refresh mode of the second slice chip based on the clock signal, the reset signal, and the slice ID.

26. The stacked memory device of claim 25, wherein the second slice refresh control circuit is configured to:
control the refresh operation performed on the second slice chip during a second refresh mode according to the slice ID when the reset signal is generated at a predetermined logic level to begin an initialization operation; and
control the refresh operation performed on the second slice chip during a third refresh mode according to the slice ID when the clock signal is toggled a first time after the initialization operation.

27. The stacked memory device of claim 26, wherein the second slice refresh control circuit is configured to:
control the refresh operation performed on the second slice chip during a fourth refresh mode according to the slice ID when the clock signal is toggled a second time;
control the refresh operation performed on the second slice chip during a first refresh mode according to the slice ID when the clock signal is toggled a third time; and
control the refresh operation performed on the second slice chip during the second refresh mode according to the slice ID when the clock signal is toggled a fourth time.

28. The stacked memory device of claim 25, wherein the second slice refresh control circuit comprises:
a second mode control signal generation circuit configured to generate a second mode control signal based on the mode selecting signal, the reset signal, and the slice ID;
a second refresh mode selecting signal generation circuit configured to generate a second refresh mode selecting signal according to a bit set of the second mode control signal; and
a second refresh control circuit configured to control the refresh operation on the second slice chip and select the refresh mode of the second slice chip based on the refresh bank signal and the second refresh mode selecting signal.

29. The stacked memory device of claim 19, further comprising a third slice chip stacked over the second slice chip, wherein the slice control circuit further comprises a third slice refresh control circuit configured to select the refresh mode of the third slice chip based on the clock signal, the reset signal, and the slice ID.

30. The stacked memory device of claim 29, wherein the third slice control circuit is configured to:
control the refresh operation performed on the third slice chip during a third refresh mode according to the slice ID when the reset signal is generated at a predetermined logic level to begin an initialization operation, and
control the refresh operation performed on the third slice chip during a fourth refresh mode according to the slice ID when the clock signal is toggled a first time after the initialization operation.

31. The stacked memory device of claim 30, wherein the third slice control circuit is configured to:
control the refresh operation performed on the third slice chip during a first refresh mode according to the slice ID when the clock signal is toggled a second time;
control the refresh operation performed on the third slice chip during a second refresh mode according to the slice ID when the clock signal is toggled a third time; and
control the refresh operation performed on the third slice chip during the third refresh mode according to the slice ID when the clock signal is toggled a fourth time.

32. The stacked memory device of claim 29, wherein the third slice control circuit comprises:
a third mode control signal generation circuit configured to generate a third mode control signal based on the mode selecting signal, the reset signal, and the slice ID;
a third refresh mode selecting signal generation circuit configured to generate a third refresh mode selecting signal according to a bit set of the third mode control signal; and
a third refresh control circuit configured to control the refresh operation on the third slice chip and select the refresh mode of the third slice chip based on the refresh bank signal and the third refresh mode selecting signal.

33. A method comprising:
controlling, by a slice control circuit for a first slice chip and a second slice chip of a stacked memory device, the first slice chip such that a refresh operation is performed according to a refresh mode of the first slice chip when a refresh bank signal is generated that refreshes banks included in the first slice chip and the second slice chip; and
controlling, by the slice control circuit, the second slice chip such that a refresh operation is performed according to a refresh mode of the second slice chip when a refresh bank signal is generated that refreshes banks included in the first slice chip and the second slice chip.
